(19) United States
(12) Patent Application Publication
(10) Pub. No.: US 2005/0120956 A1
(43) Pub. Date: Jun. 9, 2005

(54) Plasma processing apparatus

(76) Inventor: Masaki Suzuki, Osaka-fu (JP)

Correspondence Address: WENDEROTH, LIND & PONACK, L.L.P., 2033 K STREET N. W., SUITE 800, WASHINGTON, DC, 20006-1021, US

(21) Appl. No.: 10/901,121

(22) Filed: Jul. 29, 2004

(30) Foreign Application Priority Data
Jul. 31, 2003 (JP) 2003-283394

(51) Int. Cl. C23C 16/00

(52) U.S. Cl. 118/719; 118/723 R; 118/729

(57) ABSTRACT

A plasma processing apparatus includes a process chamber, a preliminary chamber which is disposed along a direction inclined with respect to a center axis of the process chamber and which is interruptibly communicated with the process chamber, a substrate electrode portion having a substrate placement surface on the top surface of which the substrate can be placed, a substrate electrode moving device for moving the substrate electrode portion between a plasma processing position within the process chamber and a substrate delivery position within the preliminary chamber while maintaining the substrate placement surface generally horizontal, and a lid portion which is provided in the preliminary chamber so as to be openable and closable. The substrate electrode moving device is operable to move the substrate electrode portion between the plasma processing position and the substrate delivery position along the inclined direction.

### BACKGROUND OF THE INVENTION

The present invention relates to plasma processing apparatuses such as dry etching apparatuses, plasma CVD apparatuses or sputtering apparatuses to be used for the manufacture of semiconductor or other thin-film circuits or electronic circuits.

(Prior-Art Plasma Processing Apparatus 1)

As this type of plasma processing apparatus, a variety of apparatuses have been known conventionally. As an example of such a prior-art plasma processing apparatus, a schematic view showing a schematic construction of a plasma processing apparatus 500 is shown in FIG. 11.

As shown in FIG. 11, with respect to a wafer 501 which is an example of substrates (workpieces), the plasma processing apparatus 500 is provided with a process chamber 502, which is a sealable chamber to be subject to plasma processing and a load lock chamber 503 which is a chamber to be interposed between the process chamber 502 and the exterior of the apparatus, i.e. the atmospheric space, where the load lock chamber 503 is interruptibly communicated with the process chamber 502.

The process chamber 502 is provided with: a lower electrode 504 having a placement surface 504a on which the wafer 501 is to be placed; a first rotary pump 516, which is an example of vacuum evacuator for evacuating the internal space of the process chamber 502 to a vacuum; a gas inlet 514 for supplying reactant gas into the process chamber 502; and a quartz window 512 which forms part of an outer wall of the process chamber 502 and which is placed above the placement surface 504a. Within the lower electrode 504, a heating/cooling medium circulation part (not shown) is provided to control the temperature of the substrate placement surface 504a. Further, piping (not shown) for supplying a heat transfer gas such as He from within the lower electrode 504 is provided on the substrate placement surface 504a to accelerate the heat transfer between the substrate 501 and the substrate placement surface 504a.

Above the quartz window 512 outside the process chamber 502, a coil 506 which is connected to a radio-frequency power, supply 508 and a matcher 510 and to which a radio-frequency power can be applied is placed so as to face the lower electrode 504 within the process chamber 502.

The load lock chamber 503, which is placed on the right side of the process chamber 502 as viewed in the figure, is interruptibly communicated with the process chamber 502 via an openable-and-closable vacuum-side gate 524. Further, the load lock chamber 503 is provided with an atmosphere-side gate 526 which is openable and closable for the outside space of the apparatus. Outside the apparatus in proximity to the atmosphere-side gate 526, is provided a wafer lifter 534 on which the wafer 501 is to be placed so as to be deliverable to and from the load lock chamber 503 through the atmosphere-side gate 526. Also in the load lock chamber 503 is provided a carrier robot 528 which works for holding the wafer 501 placed on the wafer lifter 534 by its robot arm 530 and then carrying it into the load lock chamber 503 through the atmosphere-side gate 526 and for carrying the wafer 501 into the process chamber 502 through the vacuum-side gate 524 and further placing the wafer 501 on the placement surface 504a. This carrier robot 528 is enabled to pick out the plasma-processed wafer 501 from the placement surface 504a by the robot arm 530 and carry it out to the outside of the apparatus through the vacuum-side gate 524 and the atmosphere-side gate 526. Further, in the load lock chamber 503 is provided with a second rotary pump 532 which is an example of the vacuum evacuator for evacuating the internal space of the load lock chamber 503 to a vacuum.

The lower electrode 504 of the process chamber 502 is provided with a push-up device 518 for pushing up the wafer 501 placed on the placement surface 504a from its lower side to make the wafer 501 levitated from the placement surface 504a. The push-up device 518 is equipped with a plurality of push-up pins 522 for pushing up the underside of the wafer 501, and a cylinder portion 520 for moving up and down these push-up pins 522.

The prior-art plasma processing apparatus 500 as described above is enabled to perform plasma processing on the wafer 501 that has been carried and placed on the placement surface 504a of the lower electrode 504 by the robot arm 530, and to make the processed wafer 501 levitated from the placement surface 504a by the push-up device 518 and further scooped up and carried by the robot arm 530, then extracted from the process chamber 502 (see, e.g., Japanese unexamined patent publication No. H8-124901 (FIG. 2)).

(Prior-Art Plasma Processing Apparatus 2)

Next, FIG. 12 shows a schematic view showing a schematic construction of a plasma processing apparatus 600 according to another prior-art example.

As shown in FIG. 12, the plasma processing apparatus 600 is similar to the plasma processing apparatus 500 in having a process chamber 602 and a load lock chamber 603, but differs from the plasma processing apparatus 500 structurally in that a lower electrode 604 is movable (up-and-down movable) between the process chamber 602 and the load lock chamber 603.

More specifically, as shown in FIG. 12, the process chamber 602 is equipped with a turbo-pump 616a and a first rotary pump 616b for evacuating interior of the process chamber 602, and a dielectric bell jar 612 which is placed at the upside of the process chamber 602 and which forms part of the process chamber 602. The lower electrode 604, whose upper face serves as a placement surface 604a for a wafer 601, is equipped with an electrode lifter 620 which moves up and down the placement surface 604a between a plasma processing position for the wafer 601 in the process chamber 602 and a feed-extraction position which is a position within the load lock chamber 603 below the plasma processing position and which is a position where a robot arm 630 of a carrier robot 628 feeds and extracts the wafer 601 onto the placement surface 604a. Further, at a lower portion of the lower electrode 604 is provided an interruption part 604b which can interrupt the communication between the process chamber 602 and the load lock chamber 603 by contact with part of the outer wall of the process chamber 602 while the placement surface 604a is located at the plasma processing position. As a result of this, moving the lower electrode 604 to the plasma processing position by the electrode lifter 620 allows the communication between the process chamber 602 and the load lock chamber 603 to be interrupted, while moving the lower electrode 604 to the feed-extraction position allows the interruption to be released.

In the load lock chamber 603 are provided a second rotary pump 632 for evacuating interior of the load lock chamber 603 to a vacuum, and a wafer cassette 636 for extractably accommodating therein a plurality of wafers 601. Further provided is a cassette lifter 634 for lifting and lowering the wafer cassette 636 so that a desired wafer 601 can be extracted from among the wafers 601 accommodated in the wafer cassette 636 by the robot arm 630.

Furthermore, in the lower electrode 604 and the electrode lifter 620 is provided with a push-up device 618 for pushing up the wafer 601 placed on the placement surface 604a from the lower face of the wafer 601, where the function of this push-up device 618 is similar to that of the push-up device 518 of the plasma processing apparatus 500 (see, e.g., Japanese unexamined patent publication No. 2002-299330 (FIG. 12)). Further, within the lower electrode 604, a heating/cooling medium circulation part (not shown) is provided to control the temperature of the substrate placement surface 604a. Besides, piping (not shown) for supplying a heat transfer gas such as He from within the lower electrode 604 is provided on the substrate placement surface 604a to accelerate the heat transfer between the substrate 601 and the substrate placement surface 604a.

### SUMMARY OF THE INVENTION

In recent years, there has been being made vigorous technological development for wafer or other substrates. Processes of such technological development, in many cases, involve plasma processing exerted on substrates or the like, and such plasma processing apparatuses have been finding more opportunities for not only conventional mass production use but also, principally, experiment, development and small-quantity production uses.

In such experiment, development and small-quantity production uses, wafers to be processed are not necessarily limited to disc-shaped ones, but often given by subdivided disc-shaped wafers or other special-shaped workpieces (substrates).

Therefore, in the prior-art plasma processing apparatus 500 or 600, for the plasma processing to be performed on such an abnormally shaped wafer (workpiece), there are some cases where in consideration of the handlability of the abnormally shaped wafer in its conveyance by the carrier robot 528, 628, for example, the abnormally shaped wafer as it is stuck to an upper surface of another disc-shaped wafer is carried by the carrier robot, in which state the plasma processing on the abnormally shaped wafers is performed.

In such a case, there are problems that the plasma processing would involve time for bonding and separating the wafer to and from the other disc-shaped wafer, and moreover that the abnormally shaped wafer, being stuck to the surface of the other disc-shaped wafer, would lower in its thermal conductivity to the lower electrode 504, 604, thus making it impossible to achieve proper plasma processing.

Further, in the prior-art plasma processing apparatuses 500 and 600, after subjected to the plasma processing, the wafer may often be electrified, often making it difficult to mechanically push up, for example, a compound semiconductor wafer 501, 601 having properties of thinness and weak strength without damaging the wafer and with a 100% reliability, for the push-up device 518, 618 that performs the operation of pushing up the wafer in close contact with the placement surface to thereby make the wafer levitated from the placement surface 504a, 604a. Also, the carrier robot arm 530, 630 that operates in a vacuum chamber is susceptible to small effects of the material, film quality, size, residual charge and the like of an object to be carried by the carrier robot arm 530, 630, so that occurrence of operation errors such as a fall of the carrying object from the robot is unavoidable during continued use.

For a vacuum plasma processing apparatus, once a wafer fall or the like due to wafer damage in a push-up the wafer row carrying troubles of the robot arm as described above has occurred, it would be necessary that the process chamber 502, 602, which should be kept normally at a vacuum, is set to atmospheric pressure by blowing in nitrogen gas via the gas inlet, and thereafter the quartz window 512 or bell jar 612 is removed to make the process chamber opened to the air for collection of wafer fragments. In such a case, there is a further need for cleaning inner walls of the process chamber 502 or 602 with water or alcohol to remove inner-wall depositions that have absorbed oxygen or moisture, and for performing again evacuation, baking and idle discharge to restore the process chamber atmosphere to the original state. Such trouble restoration procedure would usually take two to three hours to a half day, causing a problem of enormous time and cost losses.

Accordingly, an object of the present invention is to solve these and other problems and provide a plasma processing apparatus for performing plasma processing on substrates or the like, the plasma processing apparatus being enabled to perform proper plasma processing even for substrates of special configurations to be used for experiments and development without requiring time and labor for substrate bonding onto another disc-shaped wafer or the like while reducing the occurrence of trouble related to the conveyance of the substrate within the plasma processing apparatus.

The present invention has the following constitutions in order to achieve the above object.

According to a first aspect of the present invention, there is provided a plasma processing apparatus for generating a plasma by applying electric power (by applying radio-frequency power or DC power) and performing plasma processing on a substrate (particularly, abnormally shaped substrate or the like), comprising:
a process chamber in which the plasma processing is performed on the substrate placed inside thereof;
a preliminary chamber (load lock chamber, or a preliminary chamber for preparation of the plasma processing; the chamber may be a vacuum preliminary chamber or preliminary exhaust chamber rather than a chamber to be evacuated) which is a chamber intervening between the process chamber and outside of the apparatus (a chamber interruptibly communicated with the process chamber by one communicating hole) and which has a lid portion for interrupting the preliminary chamber from the outside of the apparatus by closing thereof and for allowing the substrate to be delivered between the outside of the apparatus and interior of the preliminary chamber by opening thereof;
an evacuator (pressure-reducing device or a first evacuator for evacuating interior of the process chamber to draw a vacuum and a second evacuator for exhausting the interior of the preliminary chamber to draw a vacuum) for evacuating (or pressure-reducing) each of interior of the process chamber and the interior of the preliminary chamber to draw a vacuum;
a reactant gas supply portion for supplying reactant gas into the process chamber;
a substrate electrode portion having a substrate placement surface on which the substrate is to be placed (directly without using any other substrate for use of carrying or the like), for performing temperature control of the placed substrate by heat transfer through the substrate placement surface during the plasma processing;
an electric power applying device for applying radio-frequency power or DC power as the electric power to a coil or an electrode provided in the process chamber; and
a substrate electrode moving device for moving the substrate electrode portion (with keeping the substrate placement surface in a horizontal position along one direction) forward and backward between a plasma processing position where the plasma processing is performed on the substrate placed on the substrate placement surface in the process chamber that has been evacuated by the evacuator and to which the reactant gas has been supplied by the reactant gas supply portion and in which a plasma has been generated by applying the electric power to the coil or electrode by the electric power applying device, and a substrate delivery position where the substrate is delivered through the opened lid portion between the outside of the apparatus and the substrate placement surface within the preliminary chamber.

According to a second aspect of the present invention, there is provided a plasma processing apparatus as defined in the first aspect, wherein the preliminary chamber is placed along a direction inclined with respect to a center axis of the process chamber; and
the substrate electrode moving device is operable to move the substrate electrode portion between the plasma processing position and the substrate delivery position along a move axis set along the inclined direction.

According to a third aspect of the present invention, there is provided a plasma processing apparatus as defined in the second aspect, wherein an angle of the inclination is any one within a range of 30 to 60 degrees.

According to a fourth aspect of the present invention, there is provided a plasma processing apparatus as defined in the first aspect, wherein the preliminary chamber is placed along a generally horizontal direction which is a direction generally perpendicular to a center axis of the process chamber; and
the substrate electrode moving device is operable to move the substrate electrode portion between the plasma processing position and the substrate delivery position along a move axis set along the generally horizontal direction.

According to a fifth aspect of the present invention, there is provided a plasma processing apparatus as defined in the first aspect, wherein the lid portion is placed so as to allow the substrate placement surface of the substrate electrode portion positioned at the substrate delivery position to be visually recognized from the outside of the apparatus, and allow the substrate to be placed onto the substrate placement surface directly (e.g., by operator's manual work) from the outside of the apparatus, in its opened state.

According to a sixth aspect of the present invention, there is provided a plasma-processing apparatus as defined in the first aspect, further comprising:
a communicating gate portion for making the process chamber and the preliminary chamber communicated with each other so as to allow the substrate electrode portion with the substrate placed thereon to pass through the communicating gate portion; and
a process chamber interruption part which is movable integrally with the substrate electrode portion and which, with the substrate electrode portion positioned to the plasma processing position, closes the communicating gate portion to interrupt the process chamber and the preliminary chamber from each other, and with the substrate electrode portion positioned to the substrate delivery position, opens the communicating gate portion to release the process chamber and the preliminary chamber from the interruption, thereby making the process chamber and the preliminary chamber communicated with each other.

According to a seventh aspect of the present invention, there is provided a plasma processing apparatus as defined in the fifth aspect, further comprising an interruption device having an openable/closable gate lid for closing the communicating gate portion to interrupt communication between the process chamber and the preliminary chamber, with the substrate electrode portion positioned to the substrate delivery position.

According to an eighth aspect of the present invention, there is provided a plasma processing apparatus as defined in the seventh aspect, further comprising:
at least two preliminary chambers communicated with the one process chamber;
at least two substrate electrode portions which are movable forward and backward between the substrate delivery position in each of the preliminary chambers and the plasma processing chamber in the process chamber (along one direction); and
at least two communicating gate portions which make the process chamber and each of the preliminary chambers communicated with each other, wherein
the substrate electrode moving device is operable to position one substrate electrode portion selected out of the substrate electrode portions to the plasma processing position and to position the other substrate electrode portion to the substrate delivery position, and
the interruption device is operable to close and interrupt the communicating gate that serves for communication between the process chamber in which the one substrate electrode portion is positioned and the preliminary chamber in which the other substrate electrode portion is positioned.

According to a ninth aspect of the present invention, there is provided a plasma processing apparatus as defined in the second aspect, further comprising a substrate electrode rotating device for rotating the substrate electrode portion about a rotational center that is given generally by the move axis of the substrate electrode portion by the substrate electrode moving device, wherein
the substrate placed on the substrate placement surface differs in placement posture (i.e., plasma processing is performed in these different processing postures) between its one placement posture at the substrate delivery position and its another processing posture at the plasma processing position.

According to a tenth aspect of the present invention, there is provided a plasma processing apparatus as defined in the first aspect, further comprising a substrate delivery device for performing delivery of the substrate between the substrate placement surface of the substrate electrode portion positioned at the substrate delivery position and the outside of the apparatus.

According to an eleventh aspect of the present invention, there is provided a plasma processing apparatus as defined in the first aspect, wherein holding of a placement position of the substrate to the substrate placement surface is fulfilled by an adhesive material which is interposed between the substrate and the substrate placement surface, and by which close contact between the substrate and the substrate placement surface is facilitated by the interior of the preliminary chamber being evacuated by the evacuator, and which allows heat transfer between the substrate and the substrate placement surface for the plasma processing.

According to a twelfth aspect of the present invention, there is provided a plasma processing apparatus as defined in the eleventh aspect, wherein the substrate electrode portion further comprises a heating device capable of heating the substrate placement surface, and
the heating device is, by heating the adhesive material, capable of aiding bonding, fixing and release of close contact between the substrate and the substrate placement surface by the adhesive material.

More specifically, there is provided a plasma processing apparatus as defined in the eleventh aspect, wherein the substrate electrode portion further comprises a heating device for performing temperature control of the substrate in the process chamber and heating the substrate placement surface,
the heating device is operable to:
for feeding the substrate in the preliminary chamber, heat the adhesive material through the substrate placement surface to melt or soften the adhesive material so that the substrate placed on the substrate placement surface and the substrate placement surface are brought into close contact with each other via the adhesive material;
for plasma processing of the substrate in the process chamber, perform solidification of the melted or softened adhesive material by lowering temperature of the heating, thereby fixing the close contact between the substrate and the substrate placement surface via the adhesive material and further fulfilling the temperature control of the substrate by heat transfer through the substrate placement surface and the adhesive material; and
for discharging of the substrate in the preliminary chamber, heat the adhesive material once again to melt or soften the solidified adhesive material, thereby aiding release of the fixing of the close contact between the substrate and the substrate placement surface by the adhesive material.

According to the first aspect of the present invention, since the substrate electrode portion is made reciprocatingly movable between the plasma processing position within the process chamber and the substrate delivery position within the preliminary chamber, the substrate fed at the substrate delivery position can be carried to the plasma processing position for the substrate along with the substrate electrode portion as the substrate is placed on the substrate placement surface of the substrate electrode portion. Conversely, the substrate that has been subjected to plasma processing at the plasma processing position can be carried to the substrate delivery position along with the substrate electrode portion. As a result of such carriage being enabled, for example, it becomes possible to feed the substrate as the substrate is placed on the substrate placement surface directly by operator's hand against the substrate electrode portion positioned at the substrate delivery position, and also to take out the placed substrate out of the apparatus by the operator's hand.

Further, by virtue of the provision of the lid portion that enables the delivery of the substrate between the substrate placement surface placed at the substrate delivery position in the preliminary chamber and the outside of the apparatus, the feed and discharge of the substrate can be achieved directly between the substrate placement surface and the outside of the apparatus.

Accordingly, for example, the substrate having characteristics of being thin and weak in its strength (e.g., compound semiconductor wafer etc.) can be carried without intervention of any carrier robot that would be employed in conventional plasma processing apparatuses, so that occurrence of carrying trouble such as drop of the wafer can be prevented, and moreover that various constraints on the configuration the substrate involved in the intervention of a carrier robot can be eliminated.

In particular, the push-up device, which would be necessary to scoop and carry the wafer placed on the substrate electrode portion in conventional plasma processing apparatuses, can be made unnecessary in the plasma processing apparatus of the this aspect. As a result of this, damage of the wafer due to the push-up pin on the substrate electrode as well as drop of the wafer, which would hitherto occur as carrying trouble, can be prevented, so that reliable carriage of the substrate can be achieved.

Also, as to the issue that chiefly only disc-shaped wafers can be carried, which has been a constraint involved in the intervention of a carrier robot, since the substrate can be carried as it is placed directly on the substrate placement surface, it becomes implementable to carry even subdivided-disc substrates or abnormally shaped substrates or the like typified by compound semiconductor wafers, so that the above issue can be solved. In particular, such abnormally shaped substrates are in many cases used for experiment and development uses, there can be provided a plasma processing apparatus suitable for such experiment and development uses.

Also, since plasma processing for the abnormally shaped substrate can be carried out as it is placed directly on the substrate placement surface without being stuck onto, for example, a disc-shaped wafer or the like, the plasma processing can be performed without impairing thermal conductivity of the abnormally shaped substrate to the substrate electrode portion. Accordingly, there can be provided a plasma processing apparatus which is capable of performing plasma processing in which the substrate temperature is maintained at an optimum one with such special-configuration substrates and which is suited for experiment and development uses and small-quantity production use.

According to the second aspect of the present invention, in the plasma processing apparatus, the preliminary chamber is disposed along such a direction as to be inclined against the process chamber center axis, the substrate electrode portion being movable along the inclined direction, e.g., a direction inclined relative to a direction perpendicular to the substrate placement surface (i.e., inclined one direction) between the plasma processing position and the substrate delivery position, i.e., being “obliquely movable.” By virtue of this, performing the move makes it possible to realize substantially “horizontal move” and “vertical move”-concurrently.

Thus, the substrate can be carried by “horizontal move” from the substrate delivery position within the preliminary chamber to the interior of the process chamber. Further, by “vertical move,” the substrate to be subjected to plasma processing can be brought close to the coil or electrode of the process chamber, by which the substrate can be exposed to a strong plasma. Although some conventional apparatuses particularly in which only “horizontal move” is performed have had a problem that the substrate can only be carried to a position far from a plasma generation portion in the process chamber, the plasma processing apparatus as described above makes it implementable to provide an apparatus that meets two requirements at the same time, i.e., one requirement for substrate carriage and the other requirement that the substrate being exposed to a strong plasma.

Further, in the constitution in which the substrate electrode portion is moved along the inclined direction as shown above, a larger space can be ensured upward of the substrate placement surface, as compared with the case where only “horizontal move” is performed. As a result of this, not only substrates of smaller configurational heights such as disc-shaped wafers or the like but also substrates of higher configurational heights and fixing jigs for substrates can be placed on the substrate placement surface, so that plasma processing on workpieces of wider varieties of configurations can be realized.

According to the third aspect of the present invention, since the angle of the inclination is any one within a range of 30 to 60 degrees, it becomes implementable to effectively obtain the above individual working effects of realizing the “horizontal move” and the “vertical move.”

According to the fourth aspect of the present invention, even in a case where the move axis of the substrate electrode portion by the substrate electrode moving device is set generally horizontal, there can be provided a plasma processing apparatus capable of obtaining the working effects by the first aspect.

According to the fifth aspect of the present invention, since the lid portion of the preliminary chamber is so placed that, in its opened state, the substrate placement surface of the substrate electrode portion positioned at the substrate delivery position can be visually recognized from the outside of the apparatus, the substrate placement surface can securely be viewed by opening the lid portion. For example, in a case where the preliminary chamber is disposed along the inclined direction, the lid portion can be provided at a side face of the preliminary chamber, which is above the substrate delivery position, in the preliminary chamber by making use of the inclination. In such a case, opening the lid portion makes it possible to reliably view the substrate placement surface from its upward. Accordingly, in the feeding operation or extraction operation by the placement of the substrate, a decision as to secure feed or reprocessing of the substrate or discharge operation of the processed substrate can be made while the state (placement state, plasma processing result, etc.) of the substrate is visually recognized. Such effects can be said to be suitable particularly for experiment and development uses in which abnormally shaped wafers or the like are more often used.

According to the sixth aspect of the present invention, by the provision of the process chamber interruption part which is movable integrally with the substrate electrode portion and which, with the substrate electrode portion positioned to the plasma processing position, closes the communicating gate portion to interrupt the process chamber and the preliminary chamber from each other, and with the substrate electrode portion positioned to the substrate delivery position, opens the communicating gate portion to release the process chamber and the preliminary chamber from the interruption, it becomes possible to perform the interruption (i.e., sealing) of the process chamber and the releasing (release of the sealing) operation by the carrying operation of the substrate. Accordingly, the plasma processing apparatus can be further simplified in construction, and gas and discharge within the process chamber never runs about into the preliminary chamber, and reliable plasma processing in which occurrence frequency of faults or the like is reduced can be made implementable.

According to the seventh aspect of the present invention, there is further provided an interruption device which, with the substrate electrode portion positioned to the substrate processing position, interrupts the process chamber and the preliminary chamber from each other. As a result of this, even in the case where the preliminary chamber is opened for the feed or discharge of the substrate, the process chamber can be maintained in a sealed state. Therefore, the interior of the process chamber can normally be maintained at an atmosphere (e.g., a state of pressure, temperature, wall-surface deposition, etc.) suitable for plasma processing, so that efficient processing can be achieved when plasma processing is performed continuously on a plurality of the substrates or the like.

According to the eighth aspect of the present invention, the preliminary chamber, the substrate electrode portion and the communicating gate portion are provided each at least two for one process chamber. Therefore, in the state that one substrate electrode portion is positioned at the plasma processing position while the other substrate electrode portion is positioned at the substrate delivery position, when the communicating gate portion is closed to make the process chamber and the preliminary chambers interrupted from each other, it is implementable that while plasma processing is performed on the substrate placed on the one substrate electrode portion, substrate delivery or the like can be performed on the other substrate electrode portion. Thus, it is possible to provide a plasma processing apparatus capable of efficient plasma processing.

According to the ninth aspect of the present invention, by the further provision of a substrate electrode rotating device for rotating the substrate electrode portion about a rotational center that is given generally by the move axis of the substrate electrode portion, it becomes possible that, with respect to the substrate placed on the substrate placement surface, its placement posture at the substrate delivery position and its processing posture at the plasma processing position can be made different from each other.

Thus, for example, in a plasma processing apparatus in which the move axis of the substrate electrode portion by the substrate electrode moving device is inclined at an inclination angle of 45 degrees with respect to the process chamber center axis, the substrate placement surface can be postured generally horizontal at the substrate delivery position of the preliminary chamber, so that the substrate can securely be placed on the substrate placement surface. Also, by holding the placement position of the substrate placed as shown above with an electrostatic chuck or the like as an example, and further by rotating the substrate electrode portion by 180 degrees about the move axis with the substrate electrode moving device while positioning the substrate electrode portion to the plasma processing position with the substrate electrode moving device, the substrate placement surface can be disposed along the generally vertical direction in the process chamber, and plasma processing can be carried out while the substrate is held in the dispositional posture. Thus, deposition of dust or the like onto the surface of the substrate can be reduced, so that an etching surface or film-deposited surface of high quality can be formed on the surface of the substrate by the plasma processing.

According to the tenth aspect of the present invention, by the further provision of a substrate delivery device for performing delivery of the substrate between the substrate placement surface of the substrate electrode portion positioned at the substrate delivery position and the outside of the apparatus, the delivery of the substrate between the substrate placement surface and the outside of the apparatus can automatically be carried out without doing manual work by an operator or the like, thus making unmanned continuous processing practicable.

According to the eleventh aspect of the present invention, by the placement of the substrate on the substrate placement surface with intervention of the adhesive material, it becomes possible that by evacuating the interior of the preliminary chamber after the placement, the adhesive material and the substrate as well as the substrate placement surface can be brought into close contact with each other while air bubbles contained in the heat-transferable adhesive material are removed. As a result, the placement position of the substrate onto the substrate placement surface can securely be held, occurrence of deterioration of the heat transferability between the substrate and the substrate placement surface due to remaining of a large amount of air bubbles can be prevented, so that heat transferability necessary for plasma processing can be ensured. Accordingly, it is possible to provide a plasma processing apparatus capable of reliable, efficient plasma processing.

According to the twelfth aspect of the present invention, since the substrate electrode portion further comprises a heating device which is capable of heating the substrate placement surface. Thus, by freely performing heating or cooling (cooling by lowering the heating temperature) of the adhesive material, the work of bonding, fixing and releasing of close contact between the substrate and the substrate placement surface by the heat-transferable adhesive material can be made easier to do, for example, by melting or softening or resolidifying of adhesive material or the like.

### BRIEF DESCRIPTION OF THE DRAWINGS

These and other aspects and features of the present invention will become clear from the following description taken in conjunction with the preferred embodiments thereof with reference to the accompanying drawings, in which:

FIG. 1 is a schematic view of a plasma processing apparatus according to a first embodiment of the present invention;

FIG. 2 is a schematic view showing a moving state of a lower electrode in the plasma processing apparatus of FIG. 1;

FIG. 3 is an enlarged view of a process chamber and the lower electrode in the plasma processing apparatus of FIG. 1;

FIG. 4 is a sectional view taken along the line C-C in the plasma processing apparatus of FIG. 2, showing the construction of a gate lid opening/closing device;

FIG. 5 is a schematic perspective view showing the way in which the wafer placement position onto the placement surface of the lower electrode;

FIG. 6 is a schematic view of a plasma processing apparatus according to a second embodiment of the present invention;

FIG. 7 is a schematic view of a plasma processing apparatus according to a third embodiment of the present invention;

FIG. 8 is a sectional view taken along the line D-O-D in the plasma processing apparatus of FIG. 7;

FIG. 9 is a schematic view of a plasma processing apparatus according to a fourth embodiment of the present invention;

FIG. 10 is a schematic view of a plasma processing apparatus according to a modification of the first embodiment;

FIG. 11 is a schematic view of a conventional plasma processing apparatus;

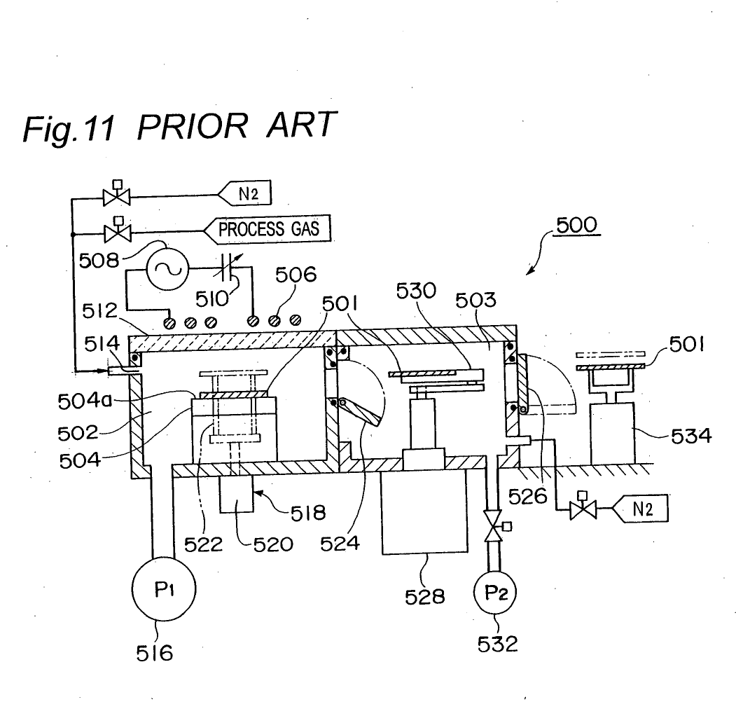

FIG. 12 is a schematic view of a plasma processing apparatus according to another conventional example;

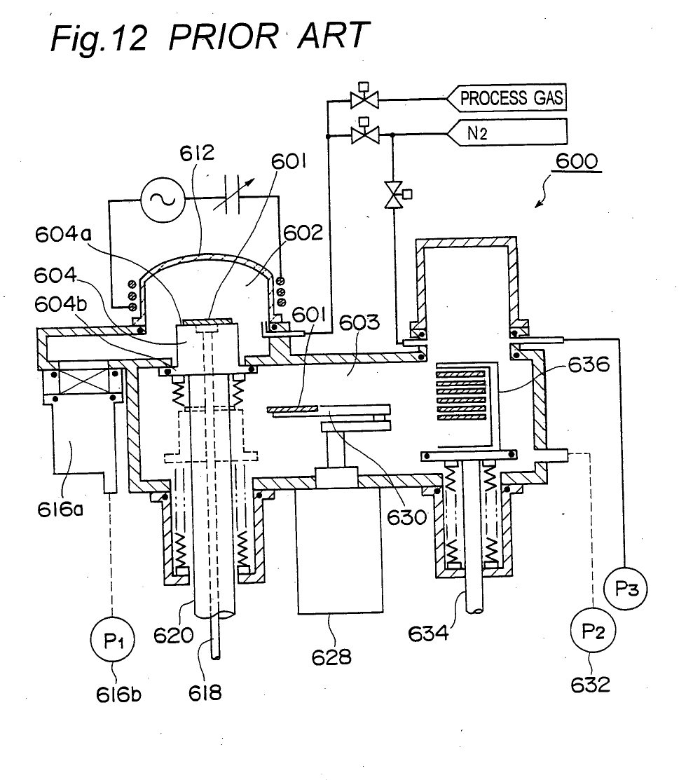

FIG. 13 is a schematic sectional view of the lower electrode according to the modification of the first embodiment; and

FIG. 14 is a schematic sectional view showing a state of trying to place the wafer on the placement surface of the lower electrode of FIG. 13.

### DETAILED DESCRIPTION OF THE PREFERRED EMBODIMENTS

Before the description of the present invention proceeds, it is to be noted that like parts are designated by like reference numerals throughout the accompanying drawings.

Hereinbelow, embodiments of the present invention are described in detail with reference to the accompanying drawings.

### First Embodiment

(Construction of Plasma Processing Apparatus)

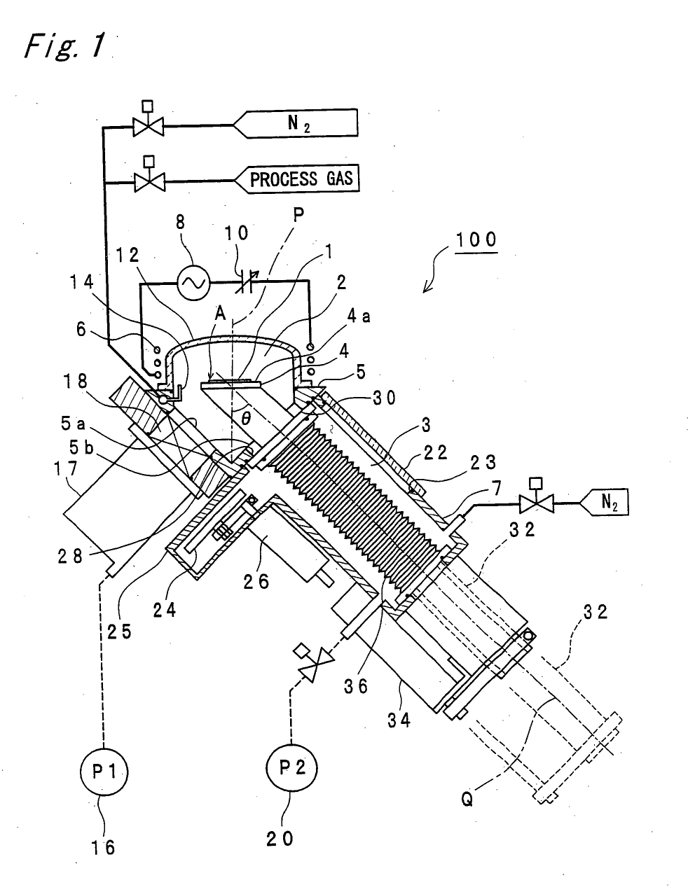

A schematic view (partial sectional view) showing a schematic construction of a plasma processing apparatus 100 according to a first embodiment of the present invention is shown in FIG. 1.

As shown in FIG. 1, the plasma processing apparatus 100 has a process chamber 2 which is a sealable chamber and in which a wafer 1, an example of substrates, is to be set, thereby making the wafer 1 subjected to specified plasma processing, and a preliminary chamber 3 (vacuum preliminary chamber or preliminary evacuation chamber) which is interposed between the process chamber 2 and the outside of the plasma processing apparatus 100 and which is a sealable chamber and further which is interruptibly communicated with the process chamber 2 by, for example, one communicating hole.

The process chamber 2 is defined inside by a process chamber vessel 5 having two planar portions 5a and 5b generally perpendicularly connected to each other in a V shape, a cylinder and a conical-shaped bottom, and a bell jar 12 which is so formed as to cover the entire top portion of the process chamber vessel 5 and which has a top plate portion of a gently curved surface shape. The bell jar 12 can be formed of a dielectric such as quartz or ceramics.

A lower electrode 4 which is an example of a substrate electrode portion having at its upper surface a placement surface 4a on which the wafer 1 can be placed can be positioned at a plasma processing position A, which is a position of a generally center portion in the process chamber 2. Also, a turbo-pump 17 for evacuating the internal space of the process chamber 2 to attain a vacuum while maintaining the chamber at a desired pressure is provided in the process chamber 2. This turbo-pump 17 is placed outside one planar portion 5a (on the left side in the figure) out of the two planar portions 5a and 5b, which form the process chamber vessel 5, so as to communicate with the internal space of the process chamber 2 via a pressure control valve 18 (for example, control valve made by VAT Vakuumventile AG., Switzerland). Also, a first rotary pump 16 is connected in series to the turbo-pump 17, making it implementable to evacuate (or reduce in pressure) the interior of the process chamber 2. It is noted that the turbo-pump 17 and the first rotary pump 16 are an example of a first evacuator in the first embodiment. The process chamber 2 has a gas inlet 14, which is an example of the reactant gas supply portion for supplying reactant gas to the internal space of the process chamber 2. In addition, a reactant gas supply pipe and a nitrogen gas supply pipe, on each of which an opening/closing valve is provided, is connected to the gas inlet 14 so that reactant gas (process gas) or nitrogen gas (N₂) can be selectively supplied.

Further, a coil 6, which is an example of a multiply-wound coil, is placed outside and around the bell jar 12 in the process chamber 2, and radio-frequency power is applied to the coil 6 through a radio-frequency power supply 8 and a matcher 10, which are an example of an electric power applying device connected to the coil 6, thus making it possible to excite a plasma within the process chamber 2 via the bell jar 12. For instance, the radio-frequency power supply 8 is enabled to apply a radio-frequency power having a frequency of 13.56 MHz and a power of 1 kW. In addition, other than such a case where the coil 6 is provided, it is also possible that with an electrode provided on an outside periphery or inside of the bell jar 12, a radio-frequency or DC power is applied to the electrode by an electric power applying device.

As shown in FIG. 1, a communicating gate 28 is formed at the other planar portion 5b (on the right side in the figure) in the process chamber vessel 5, the communicating gate 28 being an example of a communicating gate portion which is one communicating hole (opening) that communicates the process chamber 2 and the preliminary chamber 3 with each other. The preliminary chamber 3 is formed of a preliminary chamber vessel 7 having a generally hollowed prismatic shape, and the communicating gate 28 is placed at an upper portion of the prismatic shape. As a result of such a placement of the preliminary chamber 3, the preliminary chamber 3 is placed in a state that a preliminary chamber center axis Q, which is the center axis of the prismatic shape of the preliminary chamber 3, is inclined by an inclination angle θ with respect to a process chamber center axis P. It is noted that this inclination angle θ is preferably set to, for example, an angle within a range of about 30 to 60 degrees, and more preferably, an angle of about 45 degrees.

The lower electrode 4 is enabled to move with its placement surface 4a maintained generally horizontal between the plasma processing position A and a wafer delivery position B which is near a generally center of the preliminary chamber 3 and shifted along a preliminary chamber center axis B from the plasma processing position A and which an example of a substrate delivery position where delivery of the wafer 1 is done between the preliminary chamber 3 and outside of the apparatus. Also, a wafer delivery gate 23, which is an opening that makes it possible to deliver the wafer 1 between the placement surface 4a located at the wafer delivery position B and the outside of the apparatus, is formed at an upper portion, as viewed in the figure, of a side face of the inclined prismatic shape of the preliminary chamber 3, and further a lid 22, which is an example of a lid portion that can open and close the wafer delivery gate 23. Closing this lid 22 allows the internal space of the preliminary chamber 3 to be sealed, while opening the lid 22 allows the wafer 1 to be fed and discharged through the wafer delivery gate 23. This lid 22 is formed of, for example, an acrylic resin or the like, which is a transparent material, and the lid 22, when in a closed state, allows the placement surface 4a located at the wafer delivery position B to be visually recognized from the outside of the apparatus through the lid 22, that is, the lid 22 as a whole acts as an example of visualization window. This lid 22, instead of being formed wholly of the transparent material, may also be formed partly of the transparent material in a window state.

The preliminary chamber 3 is further equipped with a slide shaft 32 which is a shaft portion having the lower electrode 4 set at its upper end portion and which slidingly moves along the preliminary chamber center axis Q (which is an example of a move axis) so that the placement surface 4a can be moved between the plasma processing position A and the wafer delivery position B, and an air cylinder 34 which performs the above move of the slide shaft 32. It is noted that, in the first embodiment, the slide shaft 32 and the air cylinder 34 are an example of a substrate electrode moving device. Also, bellows 36 are set on outer peripheries of the slide shaft 32 within the preliminary chamber 3. The positioning of a move position of the slide shaft 32 to the plasma processing position A and the wafer delivery position B by the air cylinder 34 can be done mechanically by using, for example, a stopper or the like. Furthermore, in order to relieve shocks that occur when the moved slide shaft 32 is stopped at the plasma processing position A or the wafer delivery position B, it is preferable that, for example, a shock absorber is provided at the slide shaft 32.

At a connecting portion between the lower electrode 4 and the slide shaft 32 is formed an interruption part 30 (which is an example of a process chamber interruption part) which is an example of a flange-shaped flange portion so formed as to protrude from the outer periphery of the lower electrode 4. As a result of this, when the placement surface 4a is positioned to the plasma processing position A, the process chamber 2 can be sealed by making the peripheral portion of the interruption part 30 brought into contact with the periphery of the communicating gate 28 (i.e., interrupting the process chamber 2 and the preliminary chamber 3 from each other), while the contact between the peripheral portion of the interruption part 30 and the periphery of the communicating gate 28 can be released so that the process chamber 2 is released from the sealing (i.e., the interruption is released) by making the placement surface 4a moved toward the wafer delivery position B. In addition, in order to ensure such a function, the outer periphery of the lower electrode 4 is formed so as to be smaller than the opening portion of the communicating gate 28 so that, the lower electrode 4 is allowed to pass through without making contact with the communicating gate 28, while the outer periphery of the interruption part 30 is formed so as to be larger than the opening portion of the communicating gate 28 so that the peripheral portion of the interruption part 30 is securely brought into contact with the periphery of the communicating gate 28.

In the preliminary chamber 3 is provided a second rotary pump 20 which is an example of a second evacuator and which is capable of independently evacuating (or pressure-reducing) the internal space of the preliminary chamber 3 to maintain it at a specified pressure.

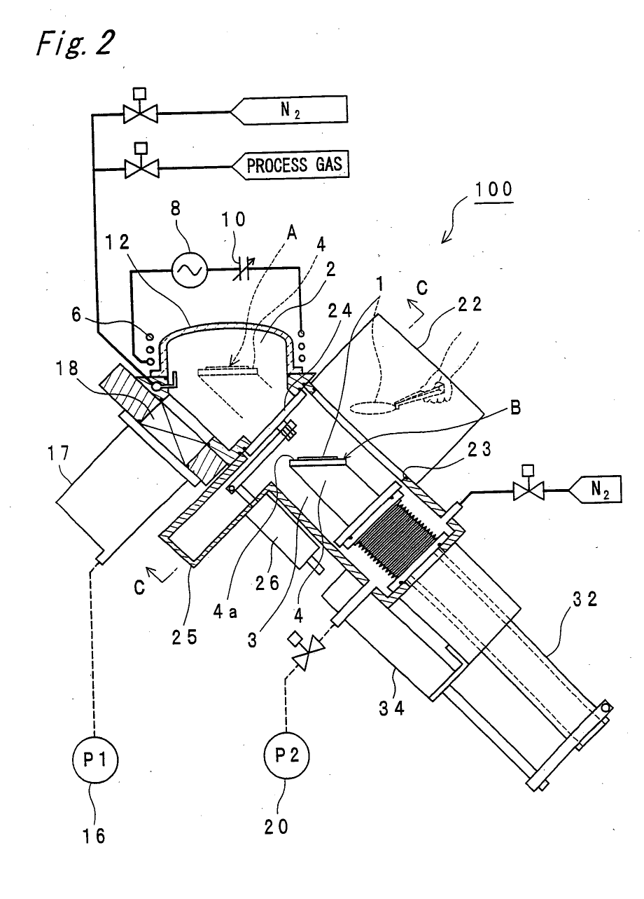

Now a schematic view showing a state of the above-described move of the lower electrode 4 in the plasma processing apparatus 100 is shown in FIG. 2.

As shown in FIG. 2, the placement surface 4a of the lower electrode 4 is set movable between the plasma processing position A (shown by broken line) within the process chamber 2 and the wafer delivery position B (shown by solid line) within the preliminary chamber 3. In the state that the placement surface 4a is located at the wafer delivery position B, the setting of the wafer delivery position B is so determined that the whole lower electrode 4 can be accommodated in the preliminary chamber 3.

Also, as shown in FIG. 2, in the state that the placement surface 4a of the lower electrode 4 is located at the wafer delivery position B, the communicating gate 28, which is a communicating portion between the process chamber 2 and the preliminary chamber 3, is set to an opened state. In order to make the process chamber 2 sealed even in such a state, the preliminary chamber 3 is equipped with a gate lid 24 that can open and close the communicating gate 28, and a gate lid opening/closing device 26 that performs the opening/closing operation of this gate lid 24. In this state, the process chamber 2 can be sealed by interrupting the process chamber 2 and the preliminary chamber 3 from each other, which is done by closing the communicating gate 28 by the gate lid 24. By sealing the process chamber 2 by using the gate lid 24 like this, for example, as shown in FIG. 2, even in a case where the preliminary chamber 3 is opened and closed to feed and discharge the wafer 1, the interior of the process chamber 2 can be maintained in a sealed state without being exposed to the atmosphere of the outside of the apparatus. It is noted that the gate lid 24 and the gate lid opening/closing device 26 is an example of the interruption device in the first embodiment.

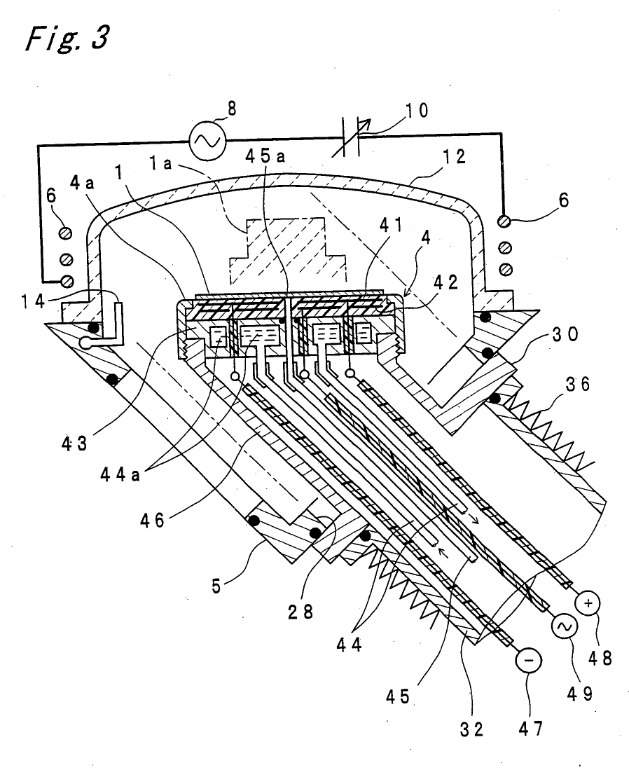

Now an enlarged schematic view of the process chamber 2 and the lower electrode 4 is shown in FIG. 3, and the construction of the lower electrode 4 and the like is explained in more detail.

As shown in FIG. 3, an ESC layer (Electro Static Chuck layer (or electrode)) 41, which is an electrode for electrostatically chucking the wafer 1 placed on the placement surface 4a in such a manner that the electrostatic chuck can be released, and a radio-frequency layer 42 that is an electrode which is placed below the ESC layer 41 and to which a radio-frequency power is applied, are provided so as to be contained inside the lower electrode 4. The ESC layer is formed in divisions on the right and left sides of the placement surface 4a as viewed in the figure, and one of those divisions is connected to an electrostatic chuck positive pole 48 and the other is connected to an electrostatic chuck negative pole 47 through electric wiring set inside the hollow slide shaft 32. Further, the radio-frequency layer 42 is connected to a bias radio-frequency power supply 49 through electric wiring set inside the slide shaft 32. By the bias radio-frequency power supply 49, for example, a radio-frequency power having a frequency of 13.56 MHz and an electric power of 200 W is applied to the radio-frequency layer 42 for the plasma processing on the wafer 1.

Further below the radio-frequency layer 42 in the lower electrode 4 is placed a water jacket 43 for heating or cooling the lower electrode 4. A plurality of cooling/heating medium flow passages 4-4a through which a cooling/heating medium fluid is permitted to flow are formed inside the water jacket 43, and a plurality of cooling/heating pipes 44 for feeding or discharging the cooling/heating medium fluid are set inside the slide shaft 32 so as to permit the cooling/heating medium fluid to pass through these cooling/heating medium flow passages 44a.

Also, between the placement surface 4a and the lower surface of the wafer 1 placed on the placement surface 4a, a heat-transfer-gas supply hole 45a for supplying a heat transfer gas is formed in proximity to a generally center of the placement surface 4a, and this heat-transfer-gas supply hole 45a is connected to a heat-transfer-gas supply pipe 45 set inside the slide shaft 32 so that heat transfer gas is suppliable. By the heat-transfer-gas supply hole 45a being formed in the placement surface 4a like this, it becomes possible to fill the heat transfer gas to minute gaps present between the lower surface of the wafer 1 and the placement surface 4a in the internal atmosphere of the process chamber 2 that is to be evacuated during plasma processing, thus making it possible to perform necessary heating or cooling with heat conduction from lower electrode 4 to the wafer 1 via the heat transfer gas. As this heat transfer gas, for example, a helium gas of an about 1000 Pa pressure (about 1/100 atmospheric pressure) is used.

The lower electrode 4 is supported by a generally cylindrical-shaped electrode support portion 46, and the interruption part 30 is formed at a lower portion of the electrode support portion 46. Further, by the slide shaft 32 being moved forward and backward, as shown in FIG. 3, a specified space which is free from contact with any other apparatus constituent portion is normally secured upward of the placement surface 4a by virtue of the inclination between the process chamber center axis P and the preliminary chamber center axis Q with the inclination angle θ even in the case where the lower electrode 4 passes through the communicating gate 28. Therefore, for example, it is also possible to set a workpiece 1a (or substrate fitting jig) having a relatively high formation height instead of the planar-shaped wafer 1 as shown in FIG. 3.

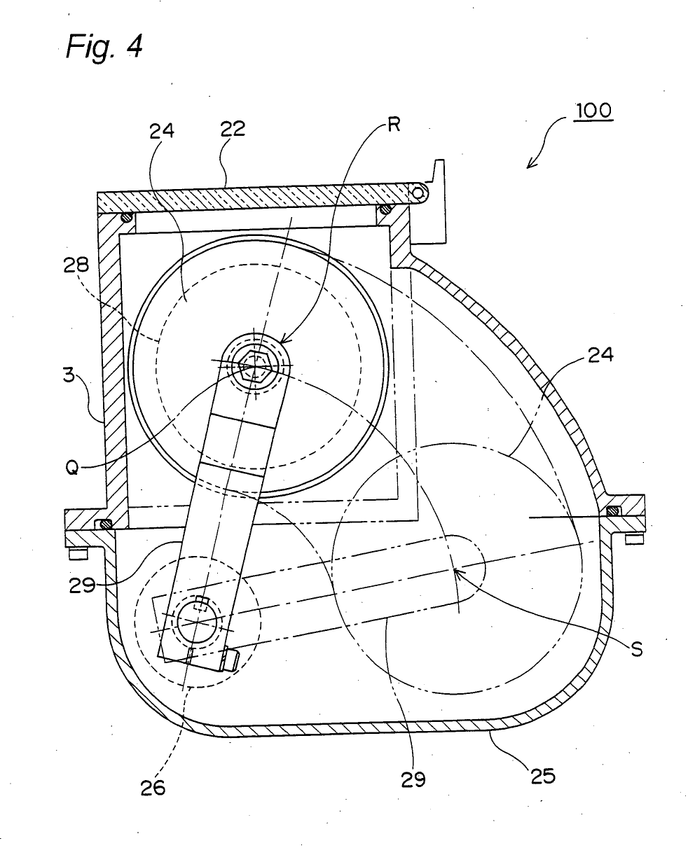

In this connection, also, a sectional view taken along the line C-C in FIG. 2 is shown in FIG. 4 as a view showing the construction of the gate lid opening/closing device 26 and the gate lid 24 in the plasma processing apparatus 100. It is noted that FIG. 4 shows a state that the lid 22 of the preliminary chamber 3 closes the wafer delivery gate 23.

As shown in FIG. 4, the gate lid 24 is fixed to the other end of a lid support portion 29 which is rotatably fixed at the rotational center of the gate lid opening/closing device 26, and the gate lid 24 can be rotated forward or reverse about the rotational center by rotationally moving the lid support portion 29 forward or reverse by the gate lid opening/closing device 26. As a result of this rotational move, the gate lid 24 can be rotationally moved between a closure position R, which is a position where the communicating gate 28 can be closed, and an open position S, which is a position where the communicating gate 28 can be opened. Also, in addition to the function of driving the rotation, the gate lid opening/closing device 26 further has a function of moving the lid support portion back and forth along the preliminary chamber center axis Q. By virtue of this, the gate lid 24 positioned at the closure position R can be moved toward the communicating gate 28 so as to be pressed thereagainst, by which the process chamber 2 can be sealed. Such back-and-forth move along the preliminary chamber center axis Q can be achieved by using, for example, a cylinder or other like mechanism, the range of the back-and-forth move being implemented by limit switch detection. More specifically, in this first embodiment, a pneumatic rotation-expansion actuator as an example is used as the gate lid opening/closing device 26. Also, as shown in FIG. 4, a lid housing chamber 25 which can house the gate lid 24 located at the open position S is formed in the preliminary chamber 3.

In addition, as shown in each of FIGS. 1 to 4, in the plasma processing apparatus 100, seal members are provided at necessary places in order to ensure the hermeticity of the process chamber 2 and the hermeticity of the preliminary chamber 3. Although not indicated by reference numerals in the figures, portions expressed by black circle graphics correspond to the seal members. For instance, the seal members are provided at a connecting portion between the planar portion 5a of the process chamber 2 and the control valve 18, a contact portion between the planar portion 5b and the interruption part 30 or gate lid 24, and further a contact portion between the wafer delivery gate 23 and the lid 22 in the preliminary chamber 3, or the like.

Also, as shown in FIG. 2, the wafer delivery gate 23 in the preliminary chamber 3 is formed, for example, so as to ensure enough size for an operator to carry the wafer 1 into the preliminary chamber 3 with a pair of tweezers and place the wafer 1 securely on the placement surface 4a.

Further, in the plasma processing apparatus 100, the lower electrode 4 is provided so as to be attachable to and removable from the slide shaft 32, and the case may be that different kinds of lower electrodes 4 are provided so as to be replaceable. In such a case, with respect to wafers 1 or the like of various configurations, a lower electrode 4 suited for each kind is selected and mounted on the slide shaft 32 for execution of plasma processing. In addition, the wafer delivery gate 23 in the preliminary chamber 3 is formed to such a size that replacement work by attachment and removal of the lower electrode 4 can be carried out.

(Plasma Processing Operation)

Next, with the plasma processing apparatus 100 having the above constitution, described below is plasma processing operation, which is a series of operations including the steps of feeding the wafer 1 and performing plasma processing, and then taking out the processed wafer 1 from the plasma processing apparatus 100.

First, as shown in FIG. 2, in the plasma processing apparatus 100, the placement surface 4a of the lower electrode 4 is positioned at the wafer delivery position B, and the gate lid 24 is positioned at the closure position R so that the process chamber 2 is sealed. In such a state, the lid 22 of the preliminary chamber 3 is opened and then the wafer 1 held by the operator with use of a wafer holding means such as tweezers is carried into the preliminary chamber 3 through the wafer delivery gate 23, and placed on the placement surface 4a.

Meanwhile, in this case, in the process chamber 2 in the sealed state, the turbo-pump 17 and the first rotary pump 16 are driven so that the pressure control valve 18 is opened, by which the evacuation within the process chamber 2 is started (otherwise, the case may be that the evacuation has already been started with the process chamber 2 maintained at a vacuum).

Thereafter, with the wafer 1 placed on the placement surface 4a, a specified voltage is applied to the ESC layer shown in FIG. 3, by which the wafer 1 in the placed state is electrostatically chucked on the placement surface 4a. When the operator has confirmed through the wafer delivery gate 23 that the wafer 1 has been placed securely on the placement surface 4a by this electrostatic chuck, the lid 22 is closed, by which the preliminary chamber 3 is sealed.

After the sealing of the preliminary chamber 3, the second rotary pump 20 is driven so that the evacuation in the preliminary chamber 3 is started. When the interior of the preliminary chamber 3 has come to a specified pressure or lower by this evacuation, the gate lid 24 is moved to the open position S by the gate lid opening/closing device 26, by which the process chamber 2 and the preliminary chamber 3 are communicated with each other.

Along with this, as shown in FIG. 1, the slide shaft 32 is moved along the preliminary chamber center axis Q by the air cylinder 34, by which the placement surface 4a with the wafer 1 placed thereon is moved so as to be positioned at the plasma processing position A. By the placement surface 4a being moved in this way, the peripheral portion of the interruption part 30 and the peripheral portion of the communicating gate 28 are brought into contact with each other, thus making the process chamber 2 put into a sealed state again.

Thereafter, in the process chamber 2, a specified reactant gas (process gas) is supplied through the gas inlet 14, and moreover the pressure control valve 18 operates to maintain the interior of the process chamber 2 at a specified pressure. After that, a specified radio-frequency power is applied to the radio-frequency layer 42 of the lower electrode 4, while a specified radio-frequency power is applied also to the coil 6. When this occurs, or since before this, the cooling/heating medium fluid is passed to the water jacket 43 of the lower electrode 4, by which the placement surface 4a of the lower electrode 4 is maintained at a specified temperature. Also, the heat transfer gas is supplied to the minute gaps between the lower surface of the wafer 1 and the placement surface 4a through the heat-transfer-gas supply hole 45a. Upon attainment of such a state, the wafer 1 is subjected to plasma processing.

Thereafter, after a specified time elapse, the supply of the reactant gas through the gas inlet 14 is stopped, and the application of the radio-frequency power to the coil 6 and the application of the radio-frequency power to the radio-frequency layer 42 are stopped, where the plasma processing is terminated. Further, the pressure control valve 18 is opened, so that the interior of the process chamber 2 comes to a high vacuum. After that, the slide shaft 32 is moved down along the preliminary chamber center axis Q by the air cylinder 34, so that the placement surface 4a on which the plasma-processed wafer 1 is placed is positioned to the wafer delivery position B. Also, this move of the slide shaft 32 causes the process chamber 2 to be released from sealing, so that the process chamber 2 and the preliminary chamber 3 are communicated with each other.

After that, the gate lid 24 is moved to the closure position R by the gate lid opening/closing device 26, and the communicating gate 28 is closed by the gate lid 24, by which the process chamber 2 is put into a sealed state again. Thus, by the process chamber 2 being brought into a sealed state again even after the plasma processing, the interior of the process chamber 2 can be maintained at an atmospheric state (e.g., a state of temperature, pressure, wall-surface deposition, etc.) necessary for plasma processing, so that uniformization of plasma processing for a next fed wafer 1 as well as reduction in the time required to start the processing can be achieved.

After the sealing of the process chamber 2, as shown in FIG. 2, in the preliminary chamber 3 interrupted from the process chamber 2, the valve on the pipe of the second rotary pump 20 is closed, making the vacuum state broken, by which the interior of the preliminary chamber 3 is set to an atmospheric pressure. In addition, for example, such breakage of a vacuum state can be achieved by supplying nitrogen gas into the preliminary chamber 3 by opening the opening/closing valve on a nitrogen-gas supply pipe which is connected so that nitrogen gas (N₂) can be supplied to the interior of the preliminary chamber 3. Thereafter, as the lid 22 is opened by the operator, the electrostatic chuck onto the placement surface 4a is released and, with the end portion of the wafer 1 held by using tweezers or the like, the plasma-processed wafer 1 is discharged to the outside of the plasma processing apparatus 100.

Then, in the case where a next wafer 1 is to be subjected to plasma processing, the next wafer 1 is fed to the placement surface 4a of the lower electrode 4 through the wafer delivery gate 23, where the plasma processing on the next wafer 1 can be performed by performing the above-described individual operations one after another.

In addition, the description of the above operational procedure has been done on a case where after the plasma processing has been performed, the placement surface 4a is moved to the wafer delivery position B so that the interior of the preliminary chamber 3 is brought to an atmospheric pressure state and the wafer 1 is taken out by the opening of the lid 22. However, instead of such a case, the case may be another where after the placement surface 4a has been moved to the wafer delivery position B, a plasma processing state on the wafer 1, is visually confirmed from the outside of the apparatus through the lid 22, while the preliminary chamber 3 is kept evacuated, and then, as required, the placement surface 4a is moved again to the plasma processing position A, where the plasma processing is carried out. This is because, in particular, it may be necessary to confirm the plasma processing state during the plasma processing for experiment and development uses.

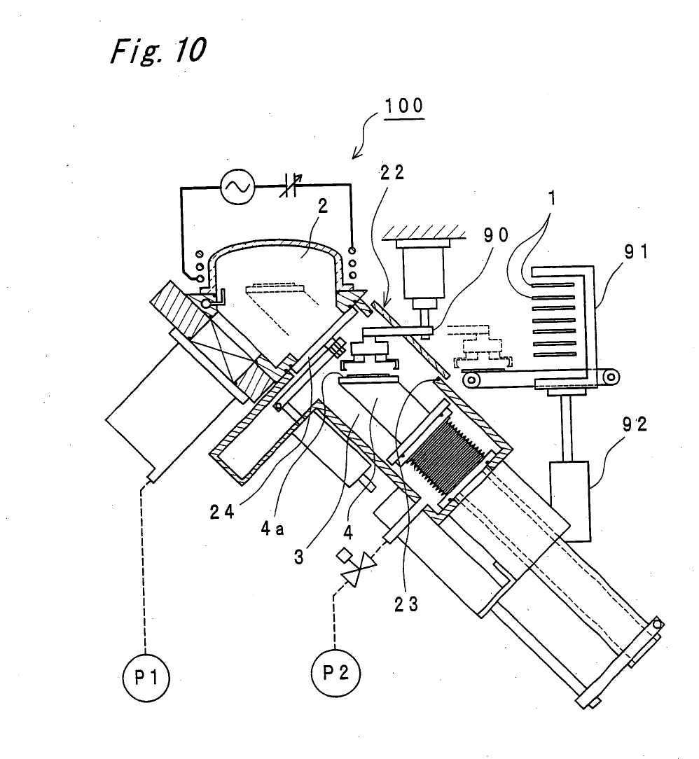

Further, the above description has been made on a case where the operator performs the feed and discharge of the wafer 1 is done by manual work against the placement surface 4a located at the wafer delivery position B in the plasma processing apparatus 100. However, the first embodiment is not limited to such cases only. For instance, instead of such a case, as shown in FIG. 10, automatic feed work and housing work of the wafer 1 can be performed by providing a transfer robot 90, which is an example of the substrate delivery device, a wafer cassette 91 in which a plurality of wafers 1 are extractably housed, and a cassette lifter 92 which makes it possible to extract a desired wafer 1 by the transfer robot 90 by moving up and down the wafer cassette 91. In addition, in such a case, the lid 22 of the preliminary chamber 3 is preferably given by adopting a slide type one in order to prevent by interference with by transfer robot 90. Further, it is also possible that by preliminary chamber 3 is enlarged so as to allow the transfer robot 90, the wafer cassette 91 and the cassette lifter 92 to be housed inside the enlarged preliminary chamber 3, where the feed and housing of the wafers 1 may be automatically performed while the preliminary chamber 3 is maintained at a vacuum.

(Method of Holding the Placement Position of Wafer)

Next, the method of holding the placement position of the wafer 1 onto the placement surface 4a of the lower electrode 4 in the plasma processing apparatus 100 is explained as its several concrete examples.

First, a first holding method of the placement position is a placement method of the wafer 1 by electrostatic chuck that has been used in the description of the foregoing plasma processing operation. This is a method in which the wafer 1 is electrostatically held by a specified voltage being applied to the ESC layer 41 contained in the lower electrode 4 as shown in FIG. 3. An electrostatic chuck can be performed by such a voltage application, and the electrostatic chuck can be released by releasing the voltage application.

Next, a second holding method of the placement position is one in which with the wafer 1 or the placement surface 4a preparatorily supplied with an adhesive agent such as wax or tackiness agent, the wafer 1 is stuck to the placement surface 4a via the adhesive or the like, thereby holding the placement position of the wafer 1.

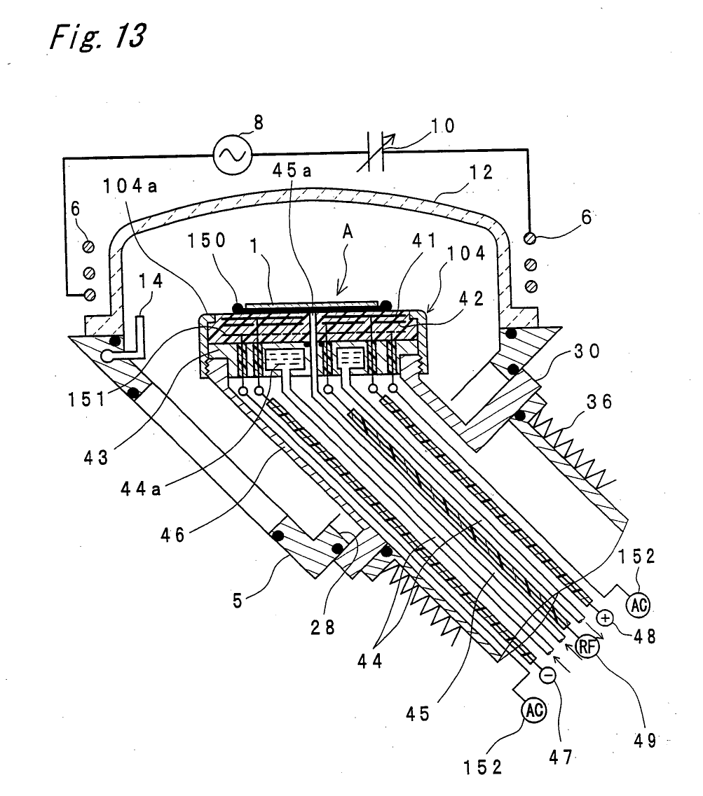

Here is explained the structure of a lower electrode 104, which is an example of the substrate electrode portion suited for this second holding method of the placement position as described above, with reference to a schematic sectional view shown in FIG. 13. It is noted that this lower electrode 104 is a modification example of the lower electrode 4 shown in FIG. 3, and its components similar in constitution to those shown in FIG. 3 are designated by like reference numerals for an easier understanding of the following explanation. Also, the lower electrode 104 differs in constitution from the lower electrode 4 shown in FIG. 3 in that the lower electrode 104 has, below its placement surface 104a, a heater electrode layer 151 which is an example of the heating device, the rest of constitution being similar to that of the lower electrode 4.

As shown in FIG. 13, an ESC layer 41 and a radio-frequency layer 42 are provided and built-in below the placement surface 104a of the lower electrode 104, and a water jacket 43 is provided further below those. A heater electrode layer 151 of high resistance is provided between those radio-frequency layer 42 and water jacket 43, and this heater electrode layer 151 is connected to an AC power supply 152 (or DC power supply) through electric wiring set inside the slide shaft 32. As a result of this, by electric power added to the heater electrode layer 151 from the AC power supply 152 through the electric wiring, the placement surface 104a can be heated by this heater electrode layer 151. Also, by controlling the amount of electric power applied to the heater electrode layer 151, the heating temperature of the placement surface 104a can be maintained at an arbitrary condition.

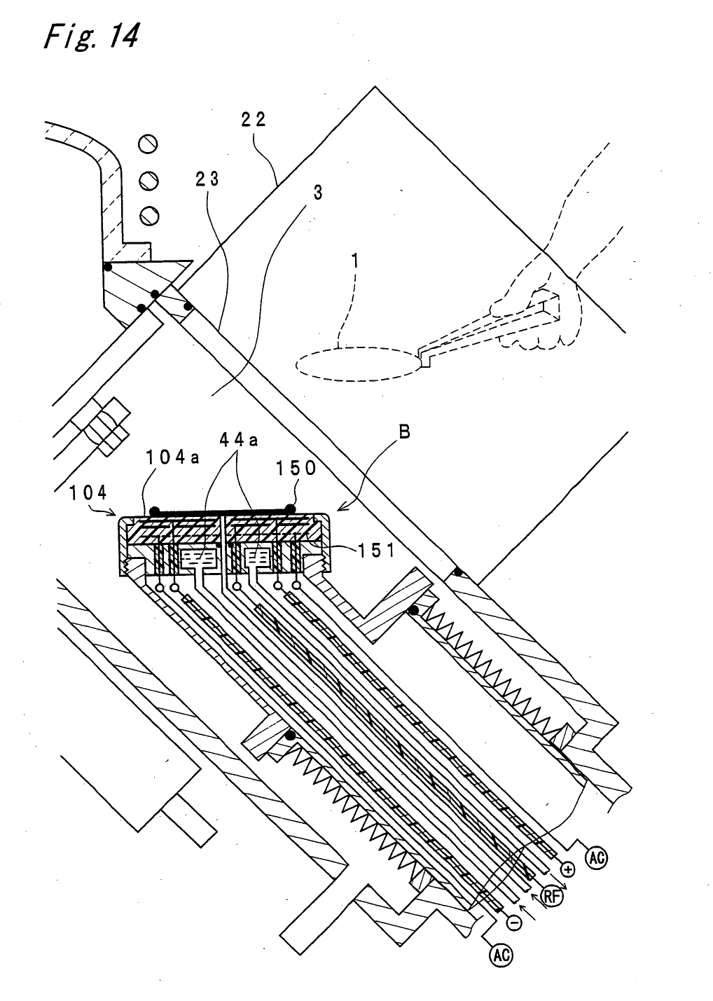

The lower electrode 104 having such a constitution is positioned to the wafer delivery position B as shown in FIG. 14, and the lid 22 is opened, where the wafer 1 can be placed on the placement surface 104a of the lower electrode 104 by the operator's manual work or the like. In this placement, in FIG. 14, by applying electric power to the heater electrode layer 151, the placement surface 104a is preparatorily heated to a specified temperature (e.g., a temperature of about 100 to 150° C.), in which state a wax 150 which is an example of adhesive material is fed and applied onto the heated placement surface 104a as shown in the figure.

It is noted here that the term, “adhesive material,” refers to an adhesive material which has heat transferability and which has both a function as a heat transfer member that performs necessary heat transfer between the placement surface 104a of the substrate electrode portion 104 and the wafer 1, and a function as an adhesive (or temporary adhesive agent) for holding the placement position of the wafer 1 to the placement surface 104a in a releasable fashion. Also, the term, “heat transfer,” refers to heat transfer that is necessary to perform plasma processing on the wafer 1, the heat transfer being necessary to control the temperature of the wafer 1 to a desired temperature by controlling the temperature of the placement surface 104a. Such an adhesive material may be given by using, for example, thermoplastic adhesives, waxes, tackiness agents, heat transfer greases (e.g., one in which alumina powder or the like is mixed with an oil that is less evaporable in a vacuum), a heat transfer sheet (e.g., one in which alumina powder, silver powder or the like is mixed with a soft resin), a vacuum grease that is less evaporable in a vacuum, and the like.

Thereafter, as shown in FIG. 14, the wafer 1 is placed onto the placement surface 104a with the wax 150 interposed therebetween. Being heated through the placement surface 104a, the wax 150 can be maintained in dissolved (or softened) state, so that the adhesion between the placement surface 104a and the wax 150 and between the wafer 1 and the wax 150 can be made better, compared with the case where the heating is not done.

Further thereafter, with the lid 22 closed, the preliminary chamber 3 is evacuated. With this evacuation, air bubbles present in the wax 150 can be reduced, so that the adhesion between the wafer 1 and the placement surface 104a and the wax 150 can be made better. Furthermore, since air bubbles are removed as shown above, the wax 150 can be enhanced in its heat transfer performance, so that the wafer 1 can be improved in temperature controllability.

After that, as shown in FIG. 13, as the lower electrode 104 is positioned to the plasma processing position A, the temperature of the heater electrode layer 151 is lowered as an example, by which the placement surface 104a is controlled to an optimum temperature necessary for plasma processing. This temperature control may also be implemented in a case where a flow of a cooling medium or heating medium through the cooling/heating medium flow passages 44a or the like is done in combination. Further, such temperature control can be carried out in a state of successful controllability by virtue of the aforementioned enhanced heat transfer performance of the wax 150. Like this, since the plasma processing is carried out in a state that the wafer 1 is controlled to a temperature suited for plasma processing through the placement surface 104a and the wax 150, a successful plasma processing can be achieved.

After the plasma processing is ended, as the lower electrode 104 is positioned to the wafer delivery position B, the wax 150 is heated through the placement surface 104a by the heater electrode layer 151. As a result of this, the solidified wax 150 can be dissolved (or softened), so that the wafer 1 can be taken out with more successful separability from the wax 150.

Further, the holding of the placement position of the wafer 1 onto the placement surface 104a can be released, that is, the wafer 1 can be separated, by holding and picking up the placed wafer 1 at its end portion or the like with tweezers or other holding means. That is, as the wax 150, one which allows the wafer 1 or the like to be easily released from its stuck state (i.e., released without breakage of the wafer 1) by applying external force to the wafer 1 or the like in the aforementioned molten state (or aforementioned softened state) of the wax.

Such a method is suitable for the placement of wafers 1 which cannot be electrostatically chucked or wafers 1 which should be kept from any electrical effects due to the electrostatic chuck. For example, the method is suitable for performing the process of substrates which are formed of a material that inhibits the electrostatic chuck from exerting its action, such as sapphire. Also, under an atmospheric pressure, placing the wafer 1 on the placement surface 104a with the wax 150 interposed therebetween and thereafter fulfilling the evacuation makes it possible to remove air bubbles contained in the wax 150 and to enhance the adhesion of the wafer 1 onto the placement surface 104a with the wax 150 interposed therebetween. As a result of this, the heat transfer performance of the wax 150 can also be enhanced, so that heat transfer necessary for plasma processing can securely be achieved.

In addition, the heating of the wax 150 may also be implemented in a case where heating or cooling by giving a flow of a cooling medium or heating medium through the cooling/heating medium flow passages 44a or the like is done in combination with the heating by the heater electrode layer 151. Otherwise, instead of the heating by the heater electrode layer 151, the case may be that only the heating/cooling by the heating medium is performed.

The lower electrode 104 shown in FIG. 13 is provided with the ESC layer 41 and the heat-transfer-gas supply hole 45ₐ. However, in an apparatus for exclusively performing the processing of wafers 1 that employ an adhesive material, since the placement position of the wafer 1 can be held by the wax 150 or the like, the ESC layer 41 can be eliminated, and moreover since the adhesion property by the wax 150 is enhanced as described above, the need for the heat-transfer-gas supply hole 45a can also be eliminated, thus making it implementable to simplify the construction of the plasma processing apparatus.

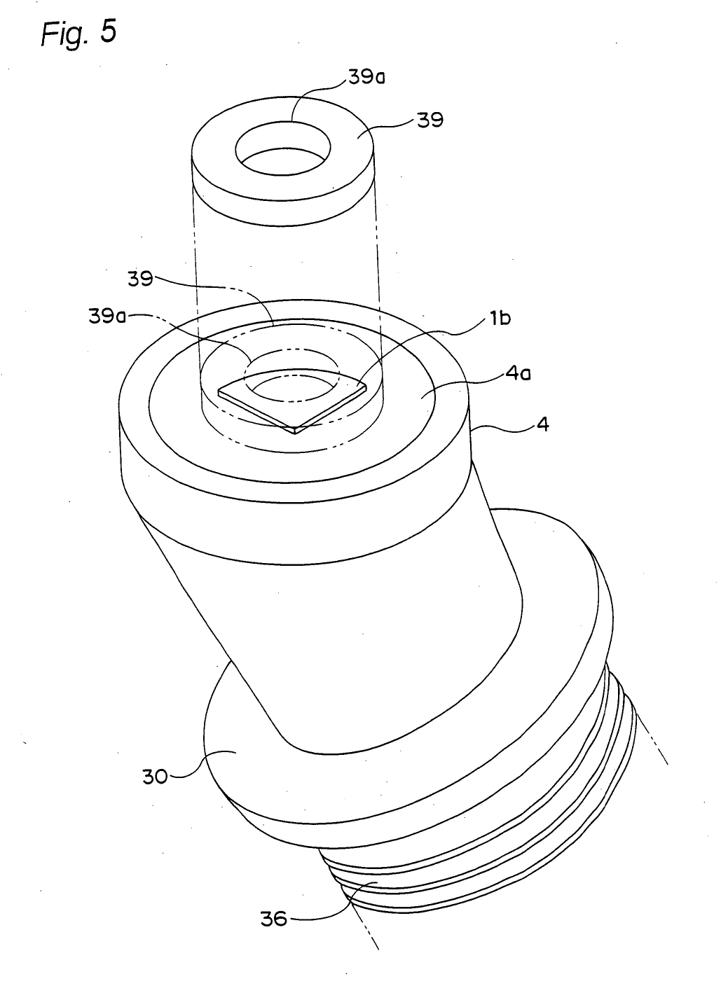

Further, a third holding method of the placement position is one in which with a weight further placed on the wafer that is placed on the placement surface 4a, the placement position of the wafer is held by the weight to counter the He pressure of the rear surface of the wafer 1. A schematic perspective view of the placement surface 4a of the lower electrode 4 while this placement method is being performed is shown in FIG. 5.

As shown in FIG. 5, an abnormally shaped wafer 1b of a quarter disc shape is placed on the placement surface 4a. Also, as a weight 39, a ring-shaped one having a circular hole 39a formed inside thereof is used. The weight measure of this weight 39 can be determined in consideration of the strength of the abnormally shaped wafer 1b, forces required for the holding of the placement position as well as for the holding of the rear surface of the wafer 1 against the He pressure, and the like. Further, the inner diameter of the circular hole 39a of the weight 39 and the external shape of the weight 39 are determined in consideration of the external shape of the abnormally shaped wafer 1b and the region subjected to plasma processing. That is, the shape of the weight 39 is so determined that, with the weight 39 placed on the abnormally shaped wafer 1b, the weight 39 is securely brought into contact with the peripheral portion of the abnormally shaped wafer 1b, making it possible to hold the placement position, while the plasma processing region in the top face of the abnormally shaped wafer 1b is positioned to within the circular hole 39a of the weight 39, thus allowing the plasma processing through the circular hole 39a to be implementable. It is of course allowable that, with weights 39 of a plurality of kinds of configurations prepared beforehand, a weight 39 best suitable for the abnormally shaped wafer 1b is selected from among those. Such a holding method of the placement position is suited for the placement of wafers 1 which should be kept from any electrical effects due to the electrostatic chuck, and has an advantage that the placement is easier to do as compared with the case where the wafer 1 is stuck by using wax or the like.

According to the individual holding methods of the placement position, in any one of those methods, while the placement position of the wafer can be securely held and moreover the wafer temperature can be maintained at a temperature best suited for plasma processing, the methods are capable of managing the holding of the placement position of wafers of various configurations because the methods are not affected by the configuration of wafers, thus suitable particularly for experiment and development uses as well as for small-quantity production use.

In addition, instead of such cases where the above individual holding methods are performed, the case may be such one in which the wafer 1 is simply placed on the placement surface 4a. Even such a method is sufficient particularly in cases where high-precision plasma processing is not required.

### Effects by the First Embodiment

According to the first embodiment, the following various working effects can be obtained.

First, by virtue of the arrangement that the lower electrode 4 provided at the fore end of the slide shaft 32 is movable forward and backward between the plasma processing position A within the process chamber 2 and the wafer delivery position B within the preliminary chamber 3, the wafer 1 can be carried to the plasma processing position A by moving the lower electrode 4 to the plasma processing position A while the wafer 1 fed at the wafer delivery position B is placed on the placement surface 4a of the lower electrode 4. Also, conversely, with the wafer 1 subjected to plasma processing at the plasma processing position A, the wafer 1 can be carried to the wafer delivery position B by moving the lower electrode 4 to the wafer delivery position B.

Furthermore, by virtue of the provisions of the wafer delivery gate 23 and the lid 22 that make the delivery of the wafer 1 to be implemented between the placement surface 4a located at the wafer delivery position B in the preliminary chamber 3 and the outside of the apparatus, the feed and discharge of the wafer 1 to the placement surface 4a can be fulfilled directly from the outside of the apparatus.

Accordingly, wafers having characteristics of being thin and weak in its strength can be carried without intervention of any carrier robot that would be employed in conventional plasma processing apparatuses, so that occurrence of carrying trouble involved in the intervention of a carrier robot can be prevented, and moreover that constraints on the configuration and material of the substrate involved in the intervention of a carrier robot can be eliminated.

In particular, the push-up device, which would be necessary to scoop and carry the wafer placed on the lower electrode in conventional plasma processing apparatuses, can be made unnecessary in the plasma processing apparatus 100 of the first embodiment. As a result of this, occurrence of operational failures of the push-up device such as damage, drops and the like of the substrate, which would occur to conventional plasma processing apparatuses as carrying trouble, can be eliminated in the plasma processing apparatus 100, and reliable carriage of the wafer 1 can be achieved.

Also, as to the issue that only disc-shaped wafers can be carried, which has been a constraint involved in the intervention of a carrier robot, since the wafer 1 can be carried as it is placed directly on the placement surface 4a, it becomes implementable to carry even partly disc-shaped wafers or abnormally shaped wafers or the like, so that the above issue can be solved. In particular, such abnormally shaped wafers (without being limited to wafers, jigs to which a wafer is attached are also applicable) are in many cases used for experiment and development uses and small-quantity production use, there can be provided a plasma processing apparatus suitable for such experiment and development uses and small-quantity production use.

Also, since plasma processing on the abnormally shaped wafer 1b can be carried out as the abnormally shaped wafer 1b is placed directly on the placement surface 4a without being stuck onto a disc-shaped wafer, the plasma processing can be performed without impairing the thermal conductivity on the abnormally shaped wafer 1b. Accordingly, there can be provided a plasma processing apparatus which is capable of performing efficient, high-precision plasma processing on such special-configuration wafers and which is suited for experiment and development uses and small-quantity production use.

Further, the interruption part 30 which can interrupt the communicating gate 28 by being brought into contact with the peripheral portion of the communicating gate 28, which is the communicating opening portion between the process chamber 2 and the preliminary chamber 3 is provided near the connecting portion between the lower electrode 4 and the slide shaft 32. Further, the interruption can be performed by locating the placement surface 4a to the plasma processing position A, and the release of the contact can be performed by locating the placement surface 4a to the wafer delivery position B. As a result, the sealing and sealing release operation of the process chamber 2 can be performed by carrying operation of the wafer 1. Thus, the constitution of the plasma processing apparatus can be simplified to more extent, and reliable plasma processing in which occurrence frequency of faults or the like is reduced can be made implementable.

Also, in the plasma processing apparatus 100, the process chamber 2 and the preliminary chamber 3 are disposed so that the preliminary chamber center axis Q is inclined against the process chamber center axis P with an inclination angle of θ. By the lower electrode 4 being movable along the preliminary chamber center axis Q while maintaining the placement surface 4a horizontal, i.e., being “obliquely movable,” performing the move makes it possible to realize substantially “horizontal move” and “vertical move” concurrently.

Further, in the constitution in which the lower electrode 4 is moved along the inclined preliminary chamber center axis Q as shown above, a larger space can be ensured upward of the placement surface 4a, as compared with the case where only “horizontal move” is performed. As a result of this, not only workpieces of smaller configurational heights such as disc-shaped wafers 1 or the like but also workpieces of higher configurational heights can be placed on the placement surface 4a, so that plasma processing on workpieces of wider varieties of higher configurational heights can be realized.

Further, in comparison with apparatuses in which “vertical move” only is performed, an inclination of the preliminary chamber center axis Q makes it possible to provide the lid 22 on a side face of the preliminary chamber 3 upward of the placement surface 4a positioned at the wafer delivery position B, so that the placement surface 4a can be visually recognized securely from upward thereof or the wafer can be fed or extracted directly with hand through the lid 22 or with the lid 22 opened. Accordingly, in the feeding operation or extraction operation by the placement of the wafer 1, secure feed or discharge operation can be achieved while the state (placement state, plasma processing state, etc.) of the wafer 1 is visually recognized. Such effects can be said to be suitable particularly for experiment and development uses and small-quantity production use in which abnormally shaped wafers or the like are more often used.

Also, by the provisions of the gate lid 24 and the gate lid opening/closing device 26 capable of sealing the process chamber 2 which is opened with the placement surface 4a positioned at the wafer delivery position B, the process chamber 2 can be maintained at sealed state independent of the preliminary chamber 3 even in such a case where the preliminary chamber 3 is opened for the feed or discharge of the wafer 1. As a result of this, the interior of the process chamber 2 can normally be maintained at an atmosphere (a state of pressure, temperature, wall-surface deposition, etc.) suitable for plasma processing, so that efficient, uniform processing can be achieved when plasma processing is performed continuously on a plurality of wafers 1.

Also, the process chamber vessel 5 that forms a lower configuration of the process chamber 2 includes two planar portions, i.e. a planar portion, which is a communicating portion with the preliminary chamber 3, and a planar portion, which is communicated with the turbo-pump 17 serving for evacuation in such a fashion that the two planar portions are coupled with each other in a V shape, thus allowing the process chamber 2 to be reduced in volume. For instance, in the case of the “horizontal move” only or the “vertical move” only, the V-shaped configuration cannot be formed, making impossible to downsize the volume, but implementing the V-shaped process chamber vessel 5 by adopting the above “oblique move” makes it possible to downsize the process chamber 2, so that a compact apparatus can be provided.

Furthermore, by the use of the process chamber vessel 5 including such V-shaped coupled two planar portions, it becomes possible to ensure gas flow passages for evacuation simultaneously while the process chamber 2 is downsized, thus making it possible to achieve efficient, large-volume evacuation and to implement high-precision plasma processing.

### Second Embodiment

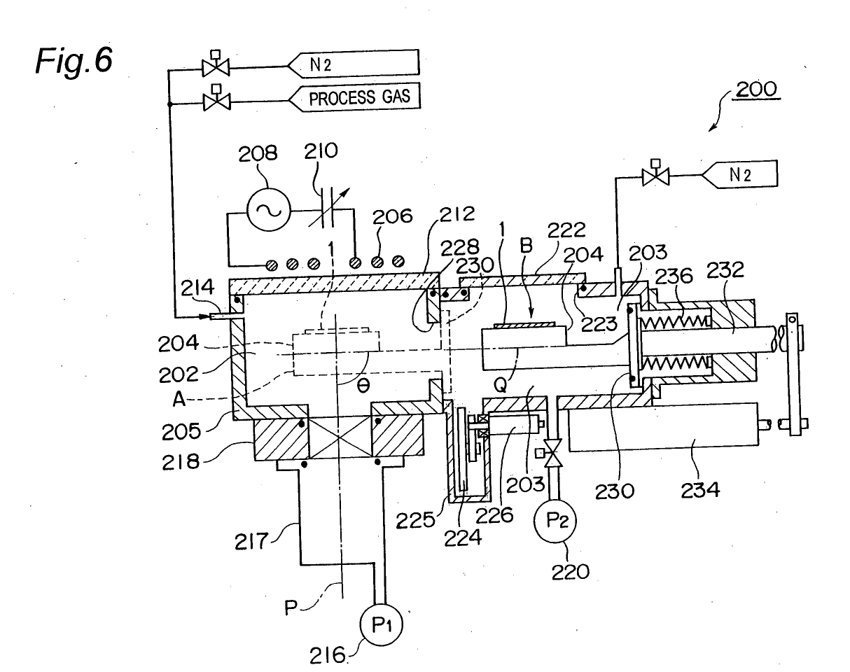

The present invention, not limited to the above embodiment, may be carried out in other various modes. For example, a schematic sectional view showing a schematic construction of a plasma processing apparatus 200 according to a second embodiment of the invention is shown in FIG. 6.

As shown in FIG. 6, the plasma processing apparatus 200 is similar in structure and function of individual components to the plasma processing apparatus 100 of the foregoing first embodiment, but differs in constitution from the plasma processing apparatus 100 in that a process chamber 202 and a preliminary chamber 203 are so arranged that the inclination angle θ between the process chamber center axis P and the preliminary chamber center axis Q becomes generally 90 degrees.

As shown in FIG. 6, the process chamber 202 is formed of a process chamber vessel 205, which is a generally cylindrical-shaped bottomed member, and a quartz window 212, which can seal in a lid shape over upper part of the process chamber vessel 205. With a proximity to a center of the process chamber 202 assumed as a plasma processing position A, a placement surface 204a of a lower electrode 204 can be positioned at the position. Also, a coil 206 to which a radio-frequency power is applied via a radio-frequency power supply 208 and a matcher 210 is provided in a wound state outside and upward of the quartz window 212.

Further, the process chamber 202 is provided with a gas inlet 214 for introducing a specified reactant gas to the interior of the process chamber 202, and a turbo-pump 217 for evacuating the interior of the process chamber 202. The turbo-pump 217 is fitted to the process chamber 202 via a control valve 218, and moreover connected to the second rotary pump 216.

As shown in FIG. 6, the preliminary chamber 203 is disposed in adjacency to the process chamber 202 on the right side thereof as viewed in the figure, and a communicating gate 228 is formed so as to make the two chambers communicated with each other. Further provided are a gate lid 224 which can open and close the communicating gate 228, a gate lid opening/closing device 226 and a lid housing chamber 225. In the preliminary chamber 203, it is made possible that the lower electrode 204 is positioned to the wafer delivery position B, which is a position near the center of the preliminary chamber 203, and a wafer delivery gate 223 which makes it possible to deliver the wafer 1 between such positioned lower electrode 204 and the outside of the apparatus as well as a lid 222 which can open and close the wafer delivery gate 223 are disposed upward of the wafer delivery position B.

The lower electrode 204 is fixed at the left end, as viewed in the figure, of a slide shaft 232 located along the preliminary chamber center axis Q, and it is made possible to move the lower electrode 204 forward and backward between the plasma processing position A and the wafer delivery position B along the preliminary chamber center axis Q by moving the slide shaft 232 forward and backward along the preliminary chamber center axis Q by an air cylinder 234.

Further, at the connecting portion between the lower electrode 204 and the slide shaft 232 is provided an interruption part 230 which is brought into contact with the peripheral portion of the communicating gate 228 by the lower electrode 204 being positioned to the plasma processing position A, to thereby releasably seal the process chamber 202.

Also, in the preliminary chamber 203, a second rotary pump 220 for evacuating the interior of the preliminary chamber 203 is provided. It is noted that the quartz window 214 and the lid 222 (made of, for example, acrylic resin) are transparent, thus making it possible to visually recognize the interior of the process chamber 202 and the interior of the preliminary chamber 203 from the outside of the apparatus.

For such a plasma processing apparatus 200, plasma processing can be carried out by an operational procedure basically similar to that of the plasma processing apparatus 100 of the first embodiment.

### Effects by the Second Embodiment

According to the second embodiment, like the working effects of the first embodiment, the feed and discharge of the wafer 1 can be performed while the placement surface 204a of the lower electrode 204 is visually recognized through the wafer delivery gate 223 in the preliminary chamber 203. Also, by virtue of the arrangement that the lower electrode 204 itself moves, there can be provided a plasma processing apparatus which can eliminate the need for a carrier robot, wafer push-up pins or the like, which would be necessary in conventional plasma processing apparatuses, so that the frequency of occurrence of operational failures can be reduced.

Further, since the wafer 1 can be carried as the wafer 1 is placed directly on the placement surface 204a of the lower electrode 204 without intervention of a carrier robot, the plasma processing apparatus is ready for plasma processing particularly on abnormally shaped workpieces.

Further, since the move direction of the lower electrode 204 is a horizontal direction, the apparatus can be downsized in the vertical direction.

### Third Embodiment

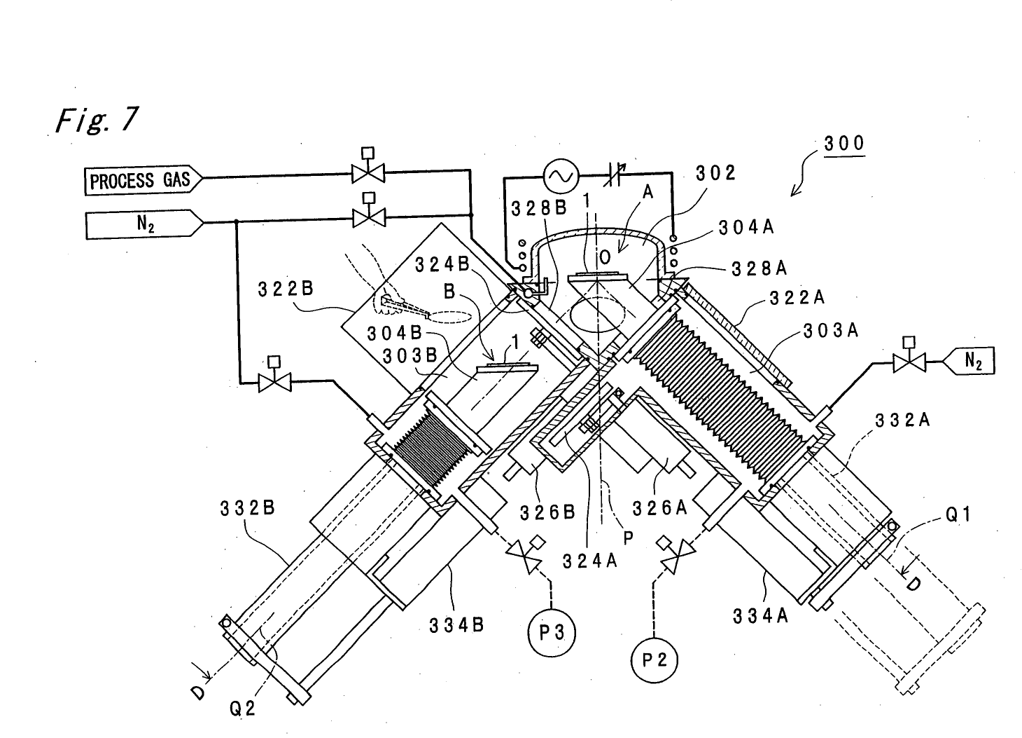

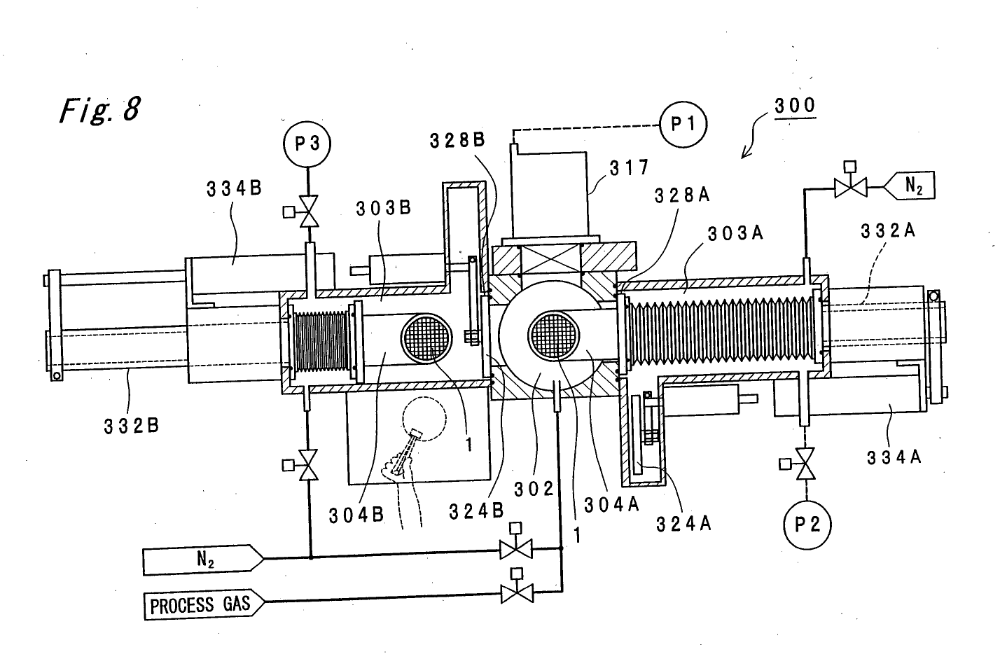

Next, a schematic sectional view showing a schematic construction of a plasma processing apparatus 300 according to a third embodiment of the present invention is shown in FIG. 7. Also, a sectional view taken along the line D-O-D in the plasma processing apparatus 300 shown in FIG. 7 is shown in FIG. 8.

As shown in FIGS. 7 and 8, the plasma processing apparatus 300 is a plasma processing apparatus which is so constructed that another preliminary chamber, another substrate electrode portion and another substrate electrode moving device are additionally provided in the plasma processing apparatus 100 of the first embodiment, that is, a plurality of preliminary chambers, a plurality of substrate electrode portions and a plurality of substrate electrode moving devices are provided for one process chamber. The plasma processing apparatus 300 is similar to the plasma processing apparatus 100 of the first embodiment in terms of the functions and uses of individual constituent components themselves, except the constituent structure that the preliminary chamber, the substrate electrode portion and the substrate electrode moving device are provided each two in quantity as shown above, and except structures related to the above constituent structure. Therefore, detailed description of the similar parts is omitted.

As shown in FIG. 7, the plasma processing apparatus 300 is provided with two preliminary chamber center axes Q1, Q2 inclined with respect to a process chamber center axis P of a process chamber 302 by an inclination angle of 45 degrees in symmetry with respect to the process chamber center axis P. Along each of the preliminary chamber center axes Q1, Q2 are provided, like the case of the plasma processing apparatus 100 of the first embodiment, preliminary chambers 303A and 303B as the two preliminary chambers, lower electrodes 304A and 304B as the two lower electrodes, and further individual constituent parts associated therewith.

Also, as shown in FIG. 8, a turbo-pump 317 serving for evacuation of the process chamber 302 is provided in connection so as to avoid the connecting portion between the two preliminary-chambers 303A and 303B in the process chamber 302. In addition, at the connecting portions between the process chamber 302 and each of the preliminary chambers 303A and 303B are provided communicating gates 328A and 328B for making those chambers with each other, respectively.

Further, the lower electrodes 304A and 304B are independently fixed to slide shafts 332A and 332B, respectively, and the slide shafts 32A and 32b can be moved independently by their respective air cylinders 334A and 334B. Also, the preliminary chambers 303A and 303B are provided with gate lids 324A and 324B, respectively, which can open and close the respective communicating gates 328A and 328B, independently.

In the plasma processing apparatus 300 having such constitution as described above, for example, with the lower electrode 304A positioned at the plasma processing position A within the process chamber 302 and with the lower electrode 304B positioned at the wafer delivery position B within the preliminary chamber 303B, the process chamber 302 and the preliminary chamber 303B can be interrupted by closing the communicating gate 328B, which is the communicating portion between the process chamber 302 and the preliminary chamber 303B. With such a state given, it becomes possible to do independent work within the process chamber 302 and the preliminary chamber 303B, respectively, without giving any influences on each other chamber. As a consequence of this, while plasma processing on the wafer 1 placed on the lower electrode 304 is carried out in the process chamber 302, the gate lid 322B is opened and delivery of the wafer 1 between the lower electrode 304B and the outside of the apparatus or other work can be carried out in the preliminary chamber 303B. Thus, it becomes implementable to achieve efficient plasma processing in the plasma processing apparatus 300.

Further, in such a case where the lower electrode 304A and the lower electrode 304B are different in kind from each other as an example, such a way of use also becomes possible as selecting an optimum lower electrode out of those lower electrodes 304A and 304B depending on the type or the like of the wafer 1 to be subjected to plasma processing. In such a case, there can be provided a plasma processing apparatus which is capable of easily and promptly making ready for a wider variety of kinds of substrates, and which can be made suitable particularly for research and development uses or small-quantity production use.

In addition, although the above description has been made on a case where the plasma processing apparatus 300 has two preliminary chambers, two substrate electrode portions and two substrate electrode moving devices, yet the third embodiment is not limited to such a case only. Instead of such a case, for example, the case may be one in which the plasma processing apparatus is provided with three or more preliminary chambers, substrate electrode portions and substrate electrode moving devices. This is because the above-described working effects can be obtained by the provision of at least two or more of those components.

Further, the above working effects can be obtained even in the case where the plurality of preliminary chambers (i.e., two or more preliminary chambers) are communicated with each other, where one preliminary chamber is disposed around one process chamber while a plurality of substrate electrode portions and substrate electrode moving devices are provided so as to be reciprocatingly movable between the one process chamber and the one preliminary chamber communicated with each other, independently of each other.

Further, although the above description has been made on a case where the two preliminary chambers 303A and 303B are disposed so as to be symmetrical to each other in the plasma processing apparatus 300, yet such symmetrical disposition is not limitative, and other various dispositions are adoptable.

### Fourth Embodiment

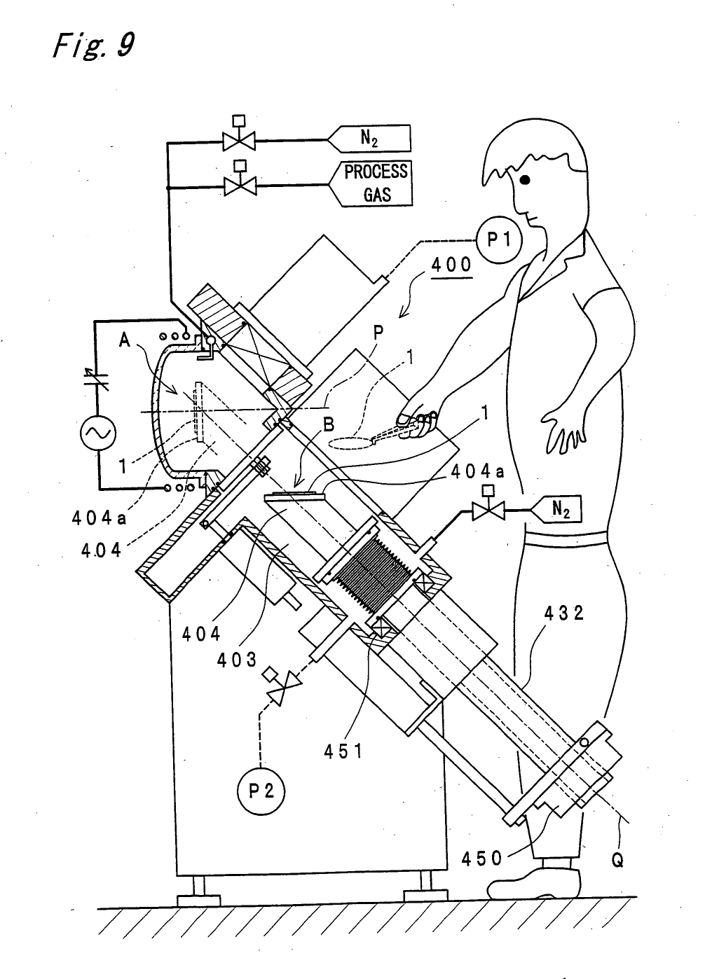

Next, a schematic sectional view showing a schematic construction of a plasma processing apparatus 400 according to a fourth embodiment of the present invention is shown in FIG. 9. As shown in FIG. 9, the plasma processing apparatus 400 is horizontal positioned on the whole of the apparatus so that the process chamber center axis P in the plasma processing apparatus 100 of the first embodiment becomes generally horizontal. Also, the functions and uses of the individual apparatus constituent components are similar to those of the plasma processing apparatus 100.

However, as shown in FIG. 9, in the plasma processing apparatus 400, a rotary actuator 450, which is an example of a substrate electrode rotating device for rotating a slide shaft 432, which performs the move operation of a lower electrode 404, about a preliminary chamber center axis Q that is the move axis of the slide shaft 432, is provided in addition to the construction of the plasma processing apparatus 100. It is noted that a rotating seal 451 is provided between the slide shaft 432 and a preliminary chamber 403, by which airtightness of the preliminary chamber 403 is maintained.

By the provision of the rotary actuator 450 like this, for example, as shown in FIG. 9, at the wafer delivery position B, the delivery of the wafer 1 can securely and easily be achieved while the lower electrode 404 has been rotated and positioned so that a placement surface 404a of the lower electrode 404 becomes generally horizontal postured. Meanwhile, in the case where with the lower electrode 404 positioned at the plasma processing position A, the wafer 1 placed thereon is subjected to plasma processing, the placement surface 404a can be postured generally vertical by rotating the lower electrode 404 by 180 degrees by the rotary actuator 450. By performing plasma processing on the wafer 1 in such a posture, the deposition amount of dust or the like onto the surface of the wafer 1 during the plasma processing can be reduced, so that etching surfaces or film-deposited surfaces of high quality can be formed. Further, in such a plasma processing apparatus 400, a placement posture of the substrate by the lower electrode 404 at the wafer delivery position B, and a placement posture of the substrate by the lower electrode 404 at the plasma processing position A can be made different from each other depending on the configuration and characteristics and the like of the substrates, thus making it possible to perform plasma processing on substrates of a wider variety of configurations and characteristics.

It is to be noted that, by properly combining the arbitrary embodiments of the aforementioned various embodiments, the effects possessed by them can be produced.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

The entire disclosure of Japanese Patent Application No. 2003-283394 filed on Jul. 31, 2003, including specification, claims, and drawings are incorporated herein by reference in its entirety.

1. A plasma processing apparatus for generating a plasma by applying electric power and performing plasma processing on a substrate, comprising:
a process chamber in which the plasma processing is performed on the substrate placed inside thereof;
a preliminary chamber which is a chamber intervening between the process chamber and outside of the apparatus and which has a lid portion for interrupting the preliminary chamber from the outside of the apparatus by closing thereof and for allowing the substrate to be delivered between the outside of the apparatus and interior of the preliminary chamber by opening thereof;
an evacuator for evacuating each of interior of the process chamber and the interior of the preliminary chamber to draw a vacuum;
a reactant gas supply portion for supplying reactant gas into the process chamber;
a substrate electrode portion having a substrate placement surface on which the substrate is to be placed, for performing temperature control of the placed substrate by heat transfer through the substrate placement surface during the plasma processing;
an electric power applying device for applying radio-frequency power or DC power as the electric power to a coil or an electrode provided in or on the process chamber; and
a substrate electrode moving device for moving the substrate electrode portion forward and backward between a plasma processing position where the plasma processing is performed on the substrate placed on the substrate placement surface in the process chamber that has been evacuated by the evacuator and to which the reactant gas has been supplied by the reactant gas supply portion and in which a plasma has been generated by applying the electric power to the coil or electrode by the electric power applying device, and a substrate delivery position where the substrate is delivered through the opened lid portion between the outside of the apparatus and the substrate placement surface within the preliminary chamber.

2. The plasma processing apparatus as defined in claim 1, wherein the preliminary chamber is placed along a direction inclined with respect to a center axis of the process chamber; and
the substrate electrode moving device is operable to move the substrate electrode portion between the plasma processing position and the substrate delivery position along a move axis set along the inclined direction.

3. The plasma processing apparatus as defined in claim 2, wherein an angle of the inclination is any one within a range of 30 to 60 degrees.

4. The plasma processing apparatus as defined in claim 1, wherein the preliminary chamber is placed along a generally horizontal direction which is a direction generally perpendicular to a center axis of the process chamber; and
the substrate electrode moving device is operable to move the substrate electrode portion between the plasma processing position and the substrate delivery position along a move axis set along the generally horizontal direction.

5. The plasma processing apparatus as defined in claim 1, wherein the lid portion is placed so as to allow the substrate placement surface of the substrate electrode portion positioned at the substrate delivery position to be visually recognized from the outside of the apparatus, and allow the substrate to be placed onto the substrate placement surface directly from the outside of the apparatus, in its opened state.

6. The plasma processing apparatus as defined in claim 1, further comprising:
a communicating gate portion for making the process chamber and the preliminary chamber communicated with each other so as to allow the substrate electrode portion with the substrate placed thereon to pass through the communicating gate portion; and
a process chamber interruption part which is movable integrally with the substrate electrode portion and which, with the substrate electrode portion positioned to the plasma processing position, closes the communicating gate portion to interrupt the process chamber and the preliminary chamber from each other, and with the substrate electrode portion positioned to the substrate delivery position, opens the communicating gate portion to release the process chamber and the preliminary chamber from the interruption, thereby making the process chamber and the preliminary chamber communicated with each other.

7. The plasma processing apparatus as defined in claim 5, further comprising an interruption device having an openable/closable gate lid for closing the communicating gate portion to interrupt communication between the process chamber and the preliminary chamber, with the substrate electrode portion positioned to the substrate delivery position.

8. The plasma processing apparatus as defined in claim 7, further comprising:
at least two preliminary chambers communicated with the one process chamber;
at least two substrate electrode portions which are movable forward and backward between the substrate delivery position in each of the preliminary chambers and the plasma processing position in the process chamber; and
at least two communicating gate portions which make the process chamber and each of the preliminary chambers communicated with each other, wherein
the substrate electrode moving device is operable to position one substrate electrode portion selected out of the substrate electrode portions to the plasma processing position and to position the other substrate electrode portion to the substrate delivery position, and
the interruption device is operable to close and interrupt the communicating gate that serves for communication between the process chamber in which the one substrate electrode portion is positioned and the preliminary chamber in which the other substrate electrode portion is positioned.

9. The plasma processing apparatus as defined in claim 2, further comprising a substrate electrode rotating device for rotating the substrate electrode portion about a rotational center that is given generally by the move axis of the substrate electrode portion by the substrate electrode moving device, wherein
the substrate placed on the substrate placement surface differs in placement posture between its one placement posture at the substrate delivery position and its another processing posture at the plasma processing position.

10. The plasma processing apparatus as defined in claim 1, further comprising a substrate delivery device for performing delivery of the substrate between the substrate placement surface of the substrate electrode portion positioned at the substrate delivery position and the outside of the apparatus.

11. The plasma processing apparatus as defined in claim 1, wherein holding of a placement position of the substrate to the substrate placement surface is fulfilled by an adhesive material which is interposed between the substrate and the substrate placement surface, and by which close contact between the substrate and the substrate placement surface is facilitated by the interior of the preliminary chamber being evacuated by the evacuator, and which allows heat transfer between the substrate and the substrate placement surface for the plasma processing.

12. The plasma processing apparatus as defined in claim 11, wherein the substrate electrode portion further comprises a heating device for performing temperature control of the substrate in the process chamber and heating the substrate placement surface,
the heating device is operable to:
for feeding the substrate in the preliminary chamber, heat the adhesive material through the substrate placement surface to melt or soften the adhesive material so that the substrate placed on the substrate placement surface and the substrate placement surface are brought into close contact with each other via the adhesive material;
for plasma processing of the substrate in the process chamber, perform solidification of the melted or softened adhesive material by lowering temperature of the heating, thereby fixing the close contact between the substrate and the substrate placement surface via the adhesive material and further fulfilling the temperature control of the substrate by heat transfer through the substrate placement surface and the adhesive material; and
for discharging of the substrate in the preliminary chamber, heat the adhesive material once again to melt or soften the solidified adhesive material, thereby aiding release of the fixing of the close contact between the substrate and the substrate placement surface by the adhesive material.
